(19) United States
(12) Patent Application Publication
(10) Pub. No.: US 2024/0333150 A1
(43) Pub. Date: Oct. 3, 2024

(54) POWER SUPPLY CIRCUIT AND POWER SUPPLY VOLTAGE SUPPLY METHOD

(71) Applicant: Murata Manufacturing Co., Ltd., Nagaokakyo-shi (JP)

(72) Inventors: John HOVERSTEN, Cambridge, MA (US); Yevgenly TKACHENKO, Cambridge, MA (US); David PERREAULT, Cambridge, MA (US); Muneyoshi YAMMAMOTO, Nagaokakyo-shi (JP); Takeshi KOGURE, Nagaokakyo-shi (JP)

(21) Appl. No.: 18/739,945

(22) Filed: Jun. 11, 2024

Related U.S. Application Data
(63) Continuation of application No. PCT/JP2023/004260, filed on Feb. 8, 2023.
(60) Provisional application No. 63/308,676, filed on Feb. 10, 2022.

(51) Int. Cl. H02M 3/07; H03F 3/24

(52) U.S. Cl. CPC H02M 3/07; H03F 3/245

(57) ABSTRACT

A power supply circuit includes a switched-capacitor circuit configured to generate, based on an input voltage, a plurality of discrete voltages; a first supply modulator configured to select, based on a first envelope signal of a first radio frequency signal, at least a first discrete voltage from the plurality of discrete voltages to output to a first power amplifier; and a second supply modulator configured to select, based on a second envelope signal of a second radio frequency signal, at least a second discrete voltage from the plurality of discrete voltages to output to a second power amplifier. The first power amplifier is configured to amplify the first radio frequency signal. The second power amplifier is configured to amplify the second radio frequency signal. The first radio frequency signal is a cellular network signal. The second radio frequency signal is a wireless local area network signal.

### CROSS REFERENCE TO RELATED APPLICATIONS

This application is a continuation of International Application No. PCT/JP2023/004260, filed Feb. 8, 2023, which claims priority to U.S. Provisional Application No. 63/308,676, filed Feb. 10, 2022, the entire contents of each of which are hereby incorporated by reference in their entirety.

### TECHNICAL FIELD

The present application relates to a power supply circuit and a power supply voltage supply method.

### BACKGROUND

Mobile communication devices, such as mobile phones, are required to be connected to a plurality of different wireless networks. For example, a typical smartphone is required to be connected to a cellular network that is based on a standard developed by the 3rd Generation Partnership Project (3GPP®) (e.g., 5th Generation New Radio (5G NR), Long Term Evolution (LTE), or the like), a wireless local area network (WLAN) that is based on a standard developed by the Institute of Electrical and Electronics Engineers (IEEE) (e.g., IEEE 802.11xx or the like), and a wireless personal area network (WPAN) that is based on Bluetooth® developed by the Bluetooth Special Interest Group (Bluetooth SIG). In 5G NR, the frequency range 2 (FR2) of 24250 MHz to 52600 MHz is used in addition to the frequency range 1 (FR1) of 450 MHz to 6000 MHz.

In mobile communication devices, a tracking mode of dynamically regulating a power supply voltage to be supplied to a power amplifier (PA) is used to improve power-added efficiency (PAE). An example circuit, such as described in United States Patent Application Publication No. 2020/0076375, can have an envelope tracking mode applied to a PA in order to improve PAE.

### SUMMARY

However, when a related envelope tracking mode, such as described in United States Patent Application Publication No. 2020/0076375, is used in a communication device compatible with a plurality of wireless networks or a plurality of frequency ranges, circuits for generating power supply voltages are necessary for individual PAs, causing an increase in the size of a power supply circuit. In addition, it may be difficult to improve the PAE in the related envelope tracking mode.

Accordingly, the exemplary aspects of the present disclosure provide a power supply circuit and a power supply voltage supply method that contribute to miniaturization and improved PAE in a communication device compatible with a plurality of wireless networks or a plurality of frequency ranges.

In an exemplary aspect, a power supply circuit of the present disclosure includes a switched-capacitor circuit that generates, from a first voltage, a plurality of discrete voltages each having a corresponding one of a plurality of discrete voltage levels; a first supply modulator that selects, based on a first envelope signal of a first radio frequency signal, at least a first discrete voltage from the plurality of discrete voltages as a first power supply voltage and that outputs the first power supply voltage to a first power amplifier configured to amplify the first radio frequency signal; and a second supply modulator that selects, based on a second envelope signal of a second radio frequency signal, at least a second discrete voltage from the plurality of discrete voltages as a second power supply voltage and that outputs the second power supply voltage to a second power amplifier configured to amplify the second radio frequency signal. In some exemplary embodiments, the first radio frequency signal is a cellular network signal, and the second radio frequency signal is a wireless local area network signal.

In another exemplary aspect, a power supply circuit of the present disclosure includes a switched-capacitor circuit that generates, from a first voltage, a plurality of discrete voltages each having a corresponding one of a plurality of discrete voltage levels; a first supply modulator that selects, based on a first envelope signal of a first radio frequency signal, at least a first discrete voltage from the plurality of discrete voltages generated by the switched-capacitor circuit as a first power supply voltage and that outputs the first power supply voltage to a first power amplifier configured to amplify the first radio frequency signal; and a second supply modulator that selects, based on a second envelope signal of a second radio frequency signal, at least a second discrete voltage from the plurality of discrete voltages generated by the switched-capacitor circuit as a second power supply voltage and that outputs the selected second power supply voltage to a second power amplifier configured to amplify the second radio frequency signal. The first radio frequency signal is a Sub6 signal of a cellular network. The second radio frequency signal is a millimeter-wave signal of a cellular network.

In another exemplary aspect, a power supply voltage supply method of the present disclosure includes generating, from a first voltage, a plurality of discrete voltages each having a corresponding one of a plurality of discrete voltage levels; selecting, based on a first envelope signal of a first radio frequency signal, at least a first discrete voltage from the plurality of discrete voltages as a first power supply voltage; selecting, based on a second envelope signal of a second radio frequency signal, at least a second discrete voltage from the plurality of discrete voltages as a second power supply voltage; supplying the first power supply voltage to a first power amplifier configured to amplify the first radio frequency signal; and supplying the second power supply voltage to a second power amplifier configured to amplify the second radio frequency signal. The first radio frequency signal is a cellular network signal. The second radio frequency signal is a wireless local area network signal.

A power supply circuit according to an exemplary aspect of the present disclosure contributes to miniaturization and improved PAE in a communication device compatible with a plurality of wireless networks or a plurality of frequency ranges.

### BRIEF DESCRIPTION OF DRAWINGS

FIG. 1A is a graph illustrating an example of transition of a power supply voltage in an average power tracking mode.

FIG. 1B is a graph illustrating an example of transition of a power supply voltage in an analog envelope tracking mode.

FIG. 1C is a graph illustrating an example of transition of a power supply voltage in a digital envelope tracking mode.

FIG. 2 is a circuit configuration diagram of a communication device according to a first exemplary embodiment.

FIG. 3A is a circuit configuration diagram of a pre-regulator circuit, a switched-capacitor circuit, supply modulators, and a filter circuit according to the first exemplary embodiment.

FIG. 3B is a circuit configuration diagram of a digital control circuit according to the first embodiment.

FIG. 4 is a flowchart illustrating a power supply voltage supply method according to the first exemplary embodiment.

FIG. 5 is a layout diagram of modules on a mother substrate according to the first exemplary embodiment.

FIG. 6 is a plan view of a tracker module according to the first exemplary embodiment.

FIG. 7 is a plan view of the tracker module according to the first exemplary embodiment.

FIG. 8 is a sectional view of the tracker module according to the first exemplary embodiment.

FIG. 9 is a plan view of power amplifier (PA) modules according to the first embodiment.

FIG. 10 is a plan view of the PA modules according to the first exemplary embodiment.

FIG. 11 is a layout diagram of modules on a mother substrate according to a second exemplary embodiment.

FIG. 12 is a plan view of a tracker module according to the second exemplary embodiment.

FIG. 13 is a layout diagram of modules on a mother substrate according to a third exemplary embodiment.

FIG. 14 is a plan view of a PA module according to the third exemplary embodiment.

FIG. 15 is a plan view of the PA module according to the third exemplary embodiment.

FIG. 16 is a circuit configuration diagram of a communication device according to a fourth exemplary embodiment.

FIG. 17 is a layout diagram of modules on a mother substrate according to the fourth exemplary embodiment.

FIG. 18 is a layout diagram of modules on a mother substrate according to a fifth exemplary embodiment.

FIG. 19 is a partial circuit configuration diagram of a communication device according to another embodiment.

### DETAILED DESCRIPTION OF EMBODIMENTS

Hereinafter, exemplary embodiments of the present disclosure will be described in detail with reference to the drawings. The exemplary embodiments described below each illustrate a general or specific example. The numerical values, shapes, materials, constituent elements, the disposition and connection manner of the constituent elements, and so forth described in the following exemplary embodiments are merely examples and are not intended to limit the present disclosure.

It is noted that the drawings are schematic diagrams drawn with emphasis, omission, or ratio adjustment performed as appropriate in order to illustrate the present disclosure. The illustration therein is not necessarily strict, and may be different from actual shapes, positional relationships, and ratios. In the drawings, components that are substantially the same are denoted by the same reference numerals, and a repeated description thereof may be omitted or simplified.

In the drawings referred to below and for purposes of this disclosure, an x-axis and a y-axis are axes orthogonal to each other on a plane parallel to main surfaces of a module laminate. According to some exemplary aspects, in a case where the module laminate has a rectangular shape in plan view, the x-axis is parallel to a first side of the module laminate, and the y-axis is parallel to a second side orthogonal to the first side of the module laminate. A z-axis is an axis perpendicular to the main surfaces of the module laminate. The positive direction thereof indicates an upward direction, and the negative direction thereof indicates a downward direction.

In the circuit configurations of the present disclosure, the term “connected” includes not only a direct connection using a connection terminal and/or a wiring conductor, but also an electrical connection via another circuit element. Moreover, the phrase “connected between A and B” means connected to both A and B between A and B, and means connected in series to a path connecting A and B.

Regarding the disposition of components in the present disclosure, the phrase “a component is disposed on or in a module laminate” includes that the component is disposed on a main surface of the module laminate and that the component is disposed in the module laminate. The phrase “a component is disposed on a main surface of a module laminate” includes not only that the component is disposed in contact with the main surface of the module laminate but also that the component is disposed above the main surface without being in contact with the main surface (for example, the component is stacked on another component disposed in contact with the main surface). The phrase “a component is disposed on a main surface of a module laminate” may include that the component is disposed in a recessed portion formed on the main surface. Moreover, the phrase “a component is disposed in a module laminate” includes not only that the component is encapsulated in the module laminate but also that the entire component is disposed between both main surfaces of the module laminate but a part of the component is not covered with the module laminate and that only a part of the component is disposed in the module laminate.

In addition, terms indicating the relationships between elements, such as “parallel” and “perpendicular”, terms indicating the shapes of elements, such as “rectangular”, and numerical ranges do not represent only strict meanings, but include substantially equivalent ranges, for example, an error of about several percent.

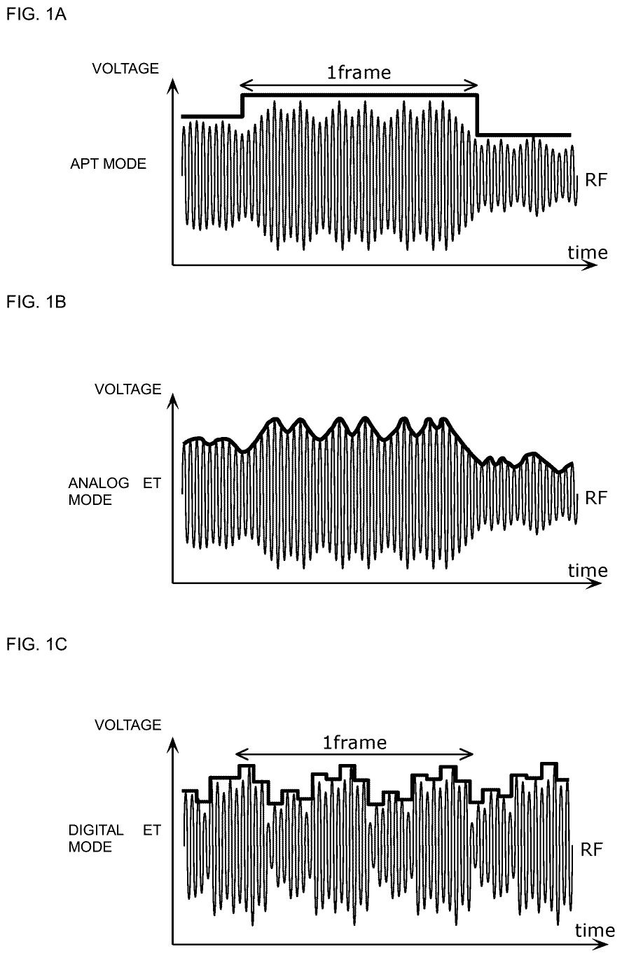

First, a description will be given of a tracking mode of supplying a power amplifier (PA) with a power supply voltage dynamically regulated based on a radio frequency (RF) signal over time, which is a technique of amplifying the RF signal with high efficiency. The tracking mode is a mode of dynamically regulating a power supply voltage to be applied to a PA circuit. Among several types of tracking modes, a description will be given here of an average power tracking (APT) mode and an envelope tracking (ET) mode (including an analog ET mode and a digital ET mode), with reference to FIG. 1A to FIG. 1C. In FIG. 1A to FIG. 1C, the horizontal axis represents time, and the vertical axis represents voltage. A thick solid line represents a power supply voltage, and a thin solid line (waveform) represents a modulated signal.

FIG. 1A is a graph illustrating an example of transition of a power supply voltage in the APT mode. In the APT mode, the power supply voltage is varied to a plurality of discrete voltage levels in units of one frame. As a result, a power supply voltage signal forms a rectangular wave. In the APT mode, the voltage level of the power supply voltage is determined based on an average output power. In the APT mode, the voltage level may be changed in units smaller than one frame (for example, in units of subframes, slots, or symbols). The APT in which the voltage level changes in units of symbols may be referred to as symbol power tracking (SPT).

For purposes of this disclosure, a frame means a unit including an RF signal (e.g., a modulated signal). For example, in 5th Generation New Radio (5G NR) and Long Term Evolution (LTE), a frame includes ten subframes, each subframe includes a plurality of slots, and each slot is formed by a plurality of symbols. The subframe has a length of 1 ms, and the frame has a length of 10 ms.

FIG. 1B is a graph illustrating an example of transition of a power supply voltage in the analog ET mode. The analog ET mode is an example of a conventional (related) ET mode. As illustrated in FIG. 1B, in the analog ET mode, the power supply voltage is continuously varied to track the envelope of a modulated signal. In the analog ET mode, the power supply voltage is determined based on an envelope signal.

The envelope signal is a signal indicating the envelope of a modulated signal. The envelope value is represented by, for example, the square root of (I2+Q2). (I, Q) represents a constellation point herein. The constellation point is a point representing, on a constellation diagram, a signal modulated by digital modulation. (I, Q) is determined by BBIC4, for example, based on transmission information.

FIG. 1C is a graph illustrating an example of transition of a power supply voltage in the digital ET mode. As illustrated in FIG. 1C, in the digital ET mode, the power supply voltage is varied to a plurality of discrete voltage levels within one frame to track the envelope of a modulated signal. As a result, a power supply voltage signal forms a rectangular wave. In the digital ET mode, a power supply voltage level is selected or set from among a plurality of discrete voltage levels, based on an envelope signal.

### First Exemplary Embodiment

Hereinafter, a first embodiment will be described. A communication device 7 according to the present exemplary embodiment can be configured to provide wireless connections. For example, the communication device 7 can be implemented in a user terminal (user equipment (UE)) in a cellular network, such as a mobile phone, a smartphone, a tablet computer, or a wearable device. In another example, the communication device 7 can be implemented to provide wireless connections to an Internet of Things (IoT) sensor device, a medical/health-care device, a vehicle, an unmanned aerial vehicle (UAV) (a so-called drone), or an automated guided vehicle (AGV). In yet another example, the communication device 7 can be implemented to provide wireless connections at a wireless access point or a wireless hotspot.

### [1.1. Circuit Configuration of Communication Device 7]

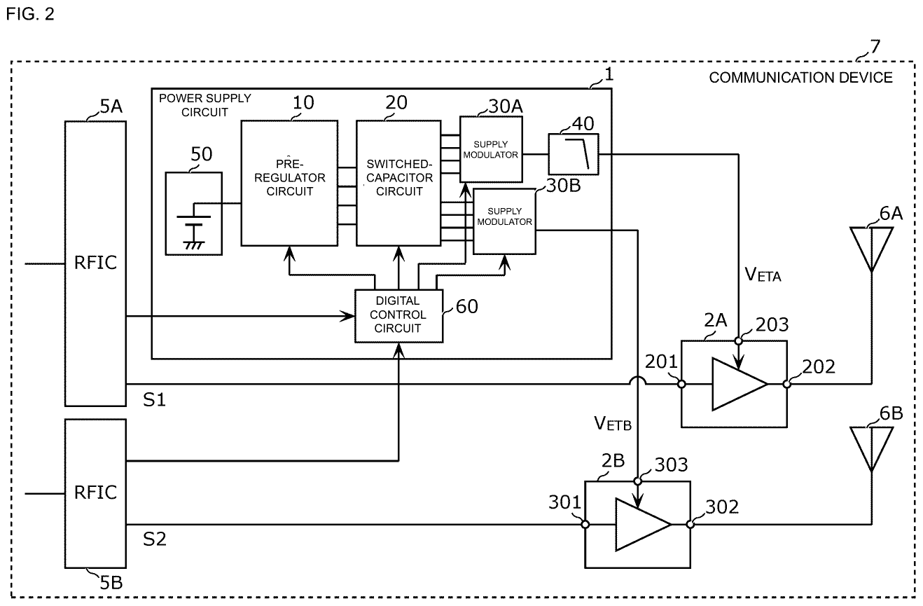

First, the circuit configuration of the communication device 7 will be described with reference to FIG. 2. FIG. 2 is a circuit configuration diagram of the communication device 7 according to the present exemplary embodiment. As illustrated in FIG. 2, the communication device 7 according to the present exemplary embodiment includes a power supply circuit 1, power amplifiers (PAS) 2A and 2B, radio frequency integrated circuits (RFICs) 5A and 5B, and antennas 6A and 6B.

The power supply circuit 1 is configured to supply power supply voltages V_{ETA} and V_{ETB} to the PAs 2A and 2B, respectively, in the digital ET mode. The power supply voltages V_{ETA} and V_{ETB} are an example of a first power supply voltage and a second power supply voltage, respectively. As described with reference to FIG. 1C, in the digital ET mode, the voltage levels of the respective power supply voltages V_{ETA} and V_{ETB} are selected, based on an envelope signal, from among a plurality of discrete voltage levels, and change with time.

Although the power supply circuit 1 supplies the two power supply voltages V_{ETA} and V_{ETB} to the two PAs 2A and 2B, respectively in FIG. 2, the power supply circuit 1 may supply the same power supply voltage to the plurality of PAs.

As illustrated in FIG. 2, the power supply circuit 1 includes a pre-regulator circuit 10, a switched-capacitor circuit 20, supply modulators 30A and 30B, a filter circuit 40, a direct-current (DC) power source 50, and a digital control circuit 60.

The pre-regulator circuit 10 includes a power inductor and a switch. The power inductor is an inductor configured to raise and/or lower a DC voltage. The power inductor is disposed in series with a signal path. Alternatively, the power inductor may be connected between a signal path and ground (disposed in parallel). The pre-regulator circuit 10 is configured to convert an input voltage into a first voltage by using the power inductor. Such a pre-regulator circuit 10 may also be referred to as a magnetic regulator or a DC-DC converter. The pre-regulator circuit 10 does not necessarily have to include a power inductor.

The switched-capacitor circuit 20 includes a plurality of capacitors and a plurality of switches, and is configured to generate, from the first voltage received from the pre-regulator circuit 10, a plurality of second voltages each having a corresponding one of a plurality of discrete voltage levels. The switched-capacitor circuit 20 may also be referred to as a switched-capacitor voltage ladder.

The supply modulators 30A and 30B are each configured to selectively output at least one of the plurality of second voltages generated by the switched-capacitor circuit 20, based on a digital control signal corresponding to an envelope signal. As a result, at least one voltage selected from among the plurality of second voltages is output from each of the supply modulators 30A and 30B. The supply modulators 30A and 30B each repeat such voltage selection with elapse of time and are thus each capable of changing an output voltage with elapse of time. The supply modulators 30A and 30B may also be referred to as output switch circuits.

The supply modulators 30A and 30B may include various circuit elements and/or wiring lines that cause a voltage drop and/or noise or the like. Thus, the time waveform of the output voltage of each of the supply modulators 30A and 30B is not necessarily a rectangular wave including only a plurality of second voltages. That is, the output voltage of each of the supply modulators 30A and 30B may include a voltage different from the plurality of second voltages.

The filter circuit 40 is configured to filter a signal (second voltage) from the supply modulator 30A.

The DC power source 50 is configured to supply a DC voltage to the pre-regulator circuit 10. The DC power source 50 may be, but is not limited to, a rechargeable battery, for example.

The digital control circuit 60 is configured to controll, based on digital control signals from the RFICs 5A and 5B, the pre-regulator circuit 10, the switched-capacitor circuit 20, and the supply modulators 30A and 30B.

In this way, the pre-regulator circuit 10 and the switched-capacitor circuit 20 are shared between the two PAs 2A and 2B, whereas the supply modulators 30A and 30B are used by the two PAs 2A and 2B, respectively.

The power supply circuit 1 does not necessarily have to include at least one of the pre-regulator circuit 10, the switched-capacitor circuit 20, the supply modulators 30A and 30B, the filter circuit 40, the DC power source 50, and the digital control circuit 60. For example, the power supply circuit 1 does not necessarily have to include the filter circuit 40. In addition, the power supply circuit 1 does not necessarily have to include the DC power source 50. Any combination of the pre-regulator circuit 10, the switched-capacitor circuit 20, the supply modulators 30A and 30B, and the filter circuit 40 may be integrated into a single circuit.

The PA 2A is an example of a first PA configured to amplify an RF signal S1, and is connected between the RFIC 5A and the antenna 6A. The PA 2A is further connected to the power supply circuit 1. According to some exemplary aspects, the PA 2A has an input terminal 201, an output terminal 202, and a power supply terminal 203. The input terminal 201 is connected to the RFIC 5A and receives the RF signal S1 from the RFIC 5A. The output terminal 202 is connected to the antenna 6A and outputs the RF signal S1 that has been amplified. The power supply terminal 203 is connected to the power supply circuit 1 and receives the power supply voltage V_{ETA}. With this connection configuration, the PA 2A is configured to amplify the RF signal S1 received from the RFIC 5A by using the power supply voltage V_{ETA} supplied from the power supply circuit 1 and outputting the RF signal S1.

The RF signal S1 is an example of a first RF signal and is a wireless communication signal in a communication network constructed using the radio access technology (RAT). In the present exemplary embodiment, the RF signal S1 is a cellular network signal, and more specifically is a Sub6 signal of a cellular network. The Sub6 signal means a signal in a frequency band below 6 GHz. In 5G NR, a Sub6 signal is a signal in a frequency band included in FR1.

The PA 2B is an example of a second PA configured to amplify an RF signal S2 and is connected between the RFIC 5B and the antenna 6B. The PA 2B is further connected to the power supply circuit 1. According to some exemplary aspects, the PA 2B has an input terminal 301, an output terminal 302, and a power supply terminal 303. The input terminal 301 is connected to the RFIC 5B and receives the RF signal S2 from the RFIC 5B. The output terminal 302 is connected to the antenna 6B and outputs the RF signal S2 that has been amplified. The power supply terminal 303 is connected to the power supply circuit 1 and receives the power supply voltage V_{ETB}. With this connection configuration, the PA 2B is configured to amplify the RF signal S2 received from the RFIC 5B by using the power supply voltage V_{ETB} supplied from the power supply circuit 1 and outputting the RF signal S2.

The RF signal S2 is an example of a second RF signal and is a wireless communication signal in a communication network constructed using the RAT. As the RF signal S2, a 2.4 GHz band signal or a 5 GHz band signal of a WLAN, or a millimeter-wave signal of a cellular network may be used. In the present exemplary embodiment, a 2.4 GHz band signal of a WLAN is used.

The millimeter-wave signal generally means a signal in a frequency band included in 30 to 300 GHz, but here means a signal in a frequency band included in 24250 to 52600 MHZ (FR2 in 5G NR).

The RFICs 5A and 5B are an example of signal processing circuits that process the RF signals S1 and S2, respectively. According to some exemplary aspects, the RFICs 5A and 5B process transmission signals input thereto by up-conversion or the like and supply the RF signals S1 and S2 generated through the signal processing to the PAs 2A and 2B, respectively. The RFICs 5A and 5B include a control unit that controls the power supply circuit 1. Some or all of the functions of the control unit of the RFICs 5A and 5B may be implemented outside the RFICs 5A and 5B (for example, in a tracker module described below).

The antenna 6A transmits the RF signal S1 received from the PA 2A. The antenna 6B transmits the RF signal S2 received from the PA 2B. The antenna 6A and/or the antenna 6B does not necessarily have to be included in the communication device 7.

The circuit configuration of the communication device 7 illustrated in FIG. 2 is illustrative and is not restrictive. For example, the communication device 7 may include a filter between the PA 2A and the antenna 6A, and/or a filter between the PA 2B and the antenna 6B.

In addition, for example, the communication device 7 may include a reception path. In this case, the RF signal S1 may be a frequency division duplex (FDD) signal, and the RF signal S2 may be a time division duplex (TDD) signal. Conversely, the RF signal S1 may be a TDD signal, and the RF signal S2 may be an FDD signal. Both of the RF signals S1 and S2 may be TDD signals or FDD signals.

### [1.2. Circuit Configuration of Power Supply Circuit 1]

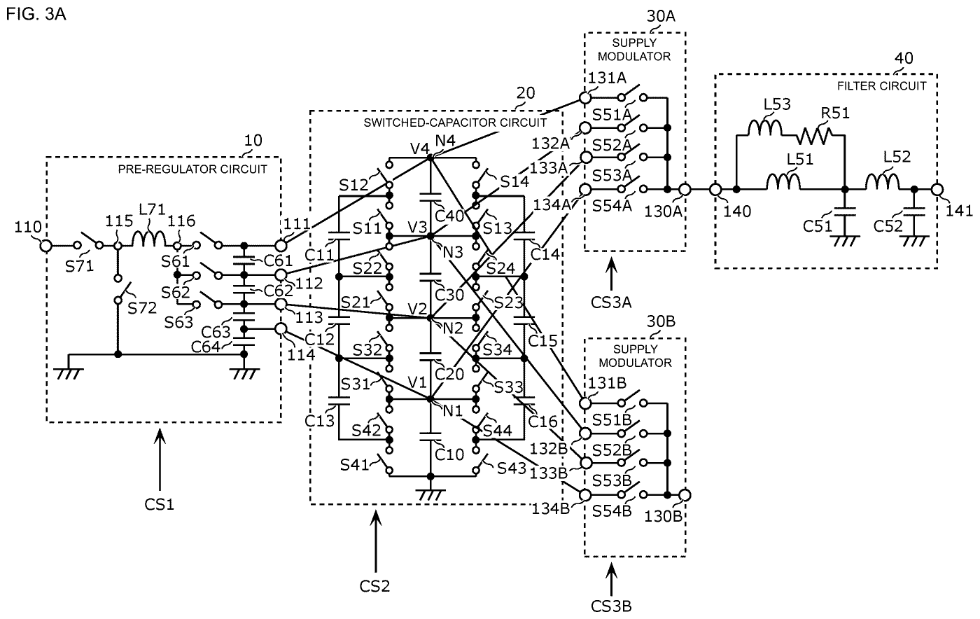

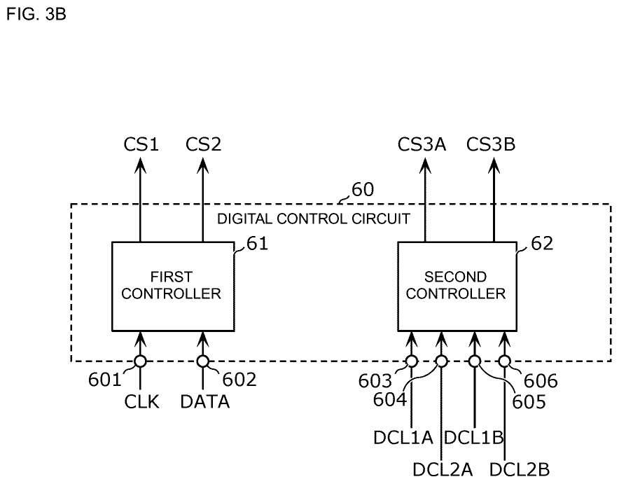

Next, the circuit configurations of the pre-regulator circuit 10, the switched-capacitor circuit 20, the supply modulators 30A and 30B, the filter circuit 40, and the digital control circuit 60 included in the power supply circuit 1 will be described with reference to FIG. 3A and FIG. 3B. FIG. 3A is a circuit configuration diagram of the pre-regulator circuit 10, the switched-capacitor circuit 20, the supply modulators 30A and 30B, and the filter circuit 40 according to the present exemplary embodiment. FIG. 3B is a circuit configuration diagram of the digital control circuit 60 according to the present exemplary embodiment.

FIG. 3A and FIG. 3B illustrate exemplary circuit configurations. The pre-regulator circuit 10, the switched-capacitor circuit 20, the supply modulators 30A and 30B, the filter circuit 40, and the digital control circuit 60 may be mounted by using any one of a wide variety of circuit packaging methods and circuit techniques. Thus, the description of the individual circuits provided below should not be construed in a limiting manner.

### [1.2.1. Circuit Configuration of Switched-Capacitor Circuit 20]

First, the circuit configuration of the switched-capacitor circuit 20 will be described. As illustrated in FIG. 3A, the switched-capacitor circuit 20 includes capacitors C11 to C16, capacitors C10, C20, C30, and C40, and switches S11 to S14, S21 to S24, S31 to S34, and S41 to S44. Energy and electric charge are input from the pre-regulator circuit 10 to the switched-capacitor circuit 20 at nodes N1 to N4 and output from the switched-capacitor circuit 20 to the supply modulators 30A and 30B at the nodes N1 to N4.

The capacitors C11 to C16 each function as a flying capacitor (also referred to as a transfer capacitor). According to some exemplary aspects, the capacitors C11 to C16 are each configured to raise or lower the first voltage supplied from the pre-regulator circuit 10. In some exemplary embodiments, the capacitors C11 to C16 cause electric charges to move between the capacitors C11 to C16 and the nodes N1 to N4 so that voltages V1 to V4 (voltages with respect to a ground potential) satisfying V1:V2:V3:V4=1:2:3:4 are maintained at the four nodes N1 to N4. The voltages V1 to V4 correspond to the plurality of second voltages each having a corresponding one of a plurality of discrete voltage levels.

The capacitor C11 has two electrodes. One of the two electrodes of the capacitor C11 is connected to one terminal of the switch S11 and one terminal of the switch S12. The other of the two electrodes of the capacitor C11 is connected to one terminal of the switch S21 and one terminal of the switch S22.

The capacitor C12 has two electrodes. One of the two electrodes of the capacitor C12 is connected to the one terminal of the switch S21 and the one terminal of the switch S22. The other of the two electrodes of the capacitor C12 is connected to one terminal of the switch S31 and one terminal of the switch S32.

The capacitor C13 has two electrodes. One of the two electrodes of the capacitor C13 is connected to the one terminal of the switch S31 and the one terminal of the switch S32. The other of the two electrodes of the capacitor C13 is connected to one terminal of the switch S41 and one terminal of the switch S42.

The capacitor C14 has two electrodes. One of the two electrodes of the capacitor C14 is connected to one terminal of the switch S13 and one terminal of the switch S14. The other of the two electrodes of the capacitor C14 is connected to one terminal of the switch S23 and one terminal of the switch S24.

The capacitor C15 has two electrodes. One of the two electrodes of the capacitor C15 is connected to the one terminal of the switch S23 and the one terminal of the switch S24. The other of the two electrodes of the capacitor C15 is connected to one terminal of the switch S33 and one terminal of the switch S34.

The capacitor C16 has two electrodes. One of the two electrodes of the capacitor C16 is connected to the one terminal of the switch S33 and the one terminal of the switch S34. The other of the two electrodes of the capacitor C16 is connected to one terminal of the switch S43 and one terminal of the switch S44.

A set of the capacitors C11 and C14, a set of the capacitors C12 and C15, and a set of the capacitors C13 and C16 can each be charged and discharged in a complementary manner as a result of a first phase and a second phase being repeated.

According to some exemplary aspects, in the first phase, the switches S12, S13, S22, S23, S32, S33, S42, and S43 are turned ON. Accordingly, for example, the one of the two electrodes of the capacitor C12 is connected to the node N3, the other of the two electrodes of the capacitor C12 and the one of the two electrodes of the capacitor C15 are connected to the node N2, and the other of the two electrodes of the capacitor C15 is connected to the node N1.

On the other hand, in the second phase, the switches S11, S14, S21, S24, S31, S34, S41, and S44 are turned ON. Accordingly, for example, the one of the two electrodes of the capacitor C15 is connected to the node N3, the other of the two electrodes of the capacitor C15 and the one of the two electrodes of the capacitor C12 are connected to the node N2, and the other of the two electrodes of the capacitor C12 is connected to the node N1.

As a result of the first phase and the second phase being repeated, for example, when one of the capacitors C12 and C15 is charged through the node N2, the other of the capacitors C12 and C15 can be discharged to the capacitor C30. In short, the capacitors C12 and C15 can be charged and discharged in a complementary manner.

Similarly to the set of the capacitors C12 and C15, the set of the capacitors C11 and C14 and the set of the capacitors C13 and C16 can each be charged and discharged in a complementary manner as a result of the first phase and the second phase being repeated.

The capacitors C10, C20, C30, and C40 each function as a smoothing capacitor. According to some exemplary aspects, the capacitors C10, C20, C30, and C40 are configured to hold and smooth the voltages V1 to V4 at the nodes N1 to N4, respectively.

The capacitor C10 is connected between the node N1 and ground. According to some exemplary aspects, one of the two electrodes of the capacitor C10 is connected to the node N1. On the other hand, the other of the two electrodes of the capacitor C10 is connected to ground.

The capacitor C20 is connected between the nodes N2 and N1. According to some exemplary aspects, one of the two electrodes of the capacitor C20 is connected to the node N2. On the other hand, the other of the two electrodes of the capacitor C20 is connected to the node N1.

The capacitor C30 is connected between the nodes N3 and N2. According to some exemplary aspects, one of the two electrodes of the capacitor C30 is connected to the node N3. On the other hand, the other of the two electrodes of the capacitor C30 is connected to the node N2.

The capacitor C40 is connected between the nodes N4 and N3. According to some exemplary aspects, one of the two electrodes of the capacitor C40 is connected to the node N4. On the other hand, the other of the two electrodes of the capacitor C40 is connected to the node N3.

The switch S11 is connected between the one of the two electrodes of the capacitor C11 and the node N3. According to some exemplary aspects, the one terminal of the switch S11 is connected to the one of the two electrodes of the capacitor C11. On the other hand, the other terminal of the switch S11 is connected to the node N3.

The switch S12 is connected between the one of the two electrodes of the capacitor C11 and the node N4. According to some exemplary aspects, the one terminal of the switch S12 is connected to the one of the two electrodes of the capacitor C11. On the other hand, the other terminal of the switch S12 is connected to the node N4.

The switch S21 is connected between the one of the two electrodes of the capacitor C12 and the node N2. According to some exemplary aspects, the one terminal of the switch S21 is connected to the one of the two electrodes of the capacitor C12 and the other of the two electrodes of the capacitor C11. On the other hand, the other terminal of the switch S21 is connected to the node N2.

The switch S22 is connected between the one of the two electrodes of the capacitor C12 and the node N3. According to some exemplary aspects, the one terminal of the switch S22 is connected to the one of the two electrodes of the capacitor C12 and the other of the two electrodes of the capacitor C11. On the other hand, the other terminal of the switch S22 is connected to the node N3.

The switch S31 is connected between the other of the two electrodes of the capacitor C12 and the node N1. According to some exemplary aspects, the one terminal of the switch S31 is connected to the other of the two electrodes of the capacitor C12 and the one of the two electrodes of the capacitor C13. On the other hand, the other terminal of the switch S31 is connected to the node N1.

The switch S32 is connected between the other of the two electrodes of the capacitor C12 and the node N2. According to some exemplary aspects, the one terminal of the switch S32 is connected to the other of the two electrodes of the capacitor C12 and the one of the two electrodes of the capacitor C13. On the other hand, the other terminal of the switch S32 is connected to the node N2. That is, the other terminal of the switch S32 is connected to the other terminal of the switch S21.

The switch S41 is connected between the other of the two electrodes of the capacitor C13 and ground. According to some exemplary aspects, the one terminal of the switch S41 is connected to the other of the two electrodes of the capacitor C13. On the other hand, the other terminal of the switch S41 is connected to ground.

The switch S42 is connected between the other of the two electrodes of the capacitor C13 and the node N1. According to some exemplary aspects, the one terminal of the switch S42 is connected to the other of the two electrodes of the capacitor C13. On the other hand, the other terminal of the switch S42 is connected to the node N1. That is, the other terminal of the switch S42 is connected to the other terminal of the switch S31.

The switch S13 is connected between the one of the two electrodes of the capacitor C14 and the node N3. According to some exemplary aspects, the one terminal of the switch S13 is connected to the one of the two electrodes of the capacitor C14. On the other hand, the other terminal of the switch S13 is connected to the node N3. That is, the other terminal of the switch S13 is connected to the other terminal of the switch S11 and the other terminal of the switch S22.

The switch S14 is connected between the one of the two electrodes of the capacitor C14 and the node N4. According to some exemplary aspects, the one terminal of the switch S14 is connected to the one of the two electrodes of the capacitor C14. On the other hand, the other terminal of the switch S14 is connected to the node N4. That is, the other terminal of the switch S14 is connected to the other terminal of the switch S12.

The switch S23 is connected between the one of the two electrodes of the capacitor C15 and the node N2. According to some exemplary aspects, the one terminal of the switch S23 is connected to the one of the two electrodes of the capacitor C15 and the other of the two electrodes of the capacitor C14. On the other hand, the other terminal of the switch S23 is connected to the node N2. That is, the other terminal of the switch S23 is connected to the other terminal of the switch S21 and the other terminal of the switch S32.

The switch S24 is connected between the one of the two electrodes of the capacitor C15 and the node N3. According to some exemplary aspects, the one terminal of the switch S24 is connected to the one of the two electrodes of the capacitor C15 and the other of the two electrodes of the capacitor C14. On the other hand, the other terminal of the switch S24 is connected to the node N3. That is, the other terminal of the switch S24 is connected to the other terminal of the switch S11, the other terminal of the switch S22, and the other terminal of the switch S13.

The switch S33 is connected between the other of the two electrodes of the capacitor C15 and the node N1. According to some exemplary aspects, the one terminal of the switch S33 is connected to the other of the two electrodes of the capacitor C15 and the one of the two electrodes of the capacitor C16. On the other hand, the other terminal of the switch S33 is connected to the node N1. That is, the other terminal of the switch S33 is connected to the other terminal of the switch S31 and the other terminal of the switch S42.

The switch S34 is connected between the other of the two electrodes of the capacitor C15 and the node N2. According to some exemplary aspects, the one terminal of the switch S34 is connected to the other of the two electrodes of the capacitor C15 and the one of the two electrodes of the capacitor C16. On the other hand, the other terminal of the switch S34 is connected to the node N2. That is, the other terminal of the switch S34 is connected to the other terminal of the switch S21, the other terminal of the switch S32, and the other terminal of the switch S23.

The switch S43 is connected between the other of the two electrodes of the capacitor C16 and ground. According to some exemplary aspects, the one terminal of the switch S43 is connected to the other of the two electrodes of the capacitor C16. On the other hand, the other terminal of the switch S43 is connected to ground.

The switch S44 is connected between the other of the two electrodes of the capacitor C16 and the node N1. According to some exemplary aspects, the one terminal of the switch S44 is connected to the other of the two electrodes of the capacitor C16. On the other hand, the other terminal of the switch S44 is connected to the node N1. That is, the other terminal of the switch S44 is connected to the other terminal of the switch S31, the other terminal of the switch S42, and the other terminal of the switch S33.

A first set of switches including the switches S12, S13, S22, S23, S32, S33, S42, and S43, and a second set of switches including the switches S11, S14, S21, S24, S31, S34, S41, and S44 are turned ON and OFF in a complementary manner. According to some exemplary aspects, in the first phase, the switches in the first set are turned ON whereas the switches in the second set are turned OFF. Conversely, in the second phase, the switches in the first set are turned OFF whereas the switches in the second set are turned ON.

For example, in one of the first phase and the second phase, charging from the capacitors C11 to C13 to the capacitors C10 to C40 is performed, and in the other of the first phase and the second phase, charging from the capacitors C14 to C16 to the capacitors C10 to C40 is performed. In other words, because the capacitors C10 to C40 are constantly charged by the capacitors C11 to C13 or the capacitors C14 to C16, the nodes N1 to N4 are rapidly replenished with electric charges even if currents rapidly flow from the nodes N1 to N4 to the supply modulators 30A and 30B. Thus, potential variations at the nodes N1 to N4 can be reduced.

As a result of operating in the above-described manner, the switched-capacitor circuit 20 is configured to maintain substantially equal voltages across each of the capacitors C10, C20, C30, and C40. According to some exemplary aspects, the voltages V1 to V4 (voltages with respect to a ground potential) satisfying V1:V2:V3:V4=1:2:3:4 are maintained at the four nodes labeled V1 to V4. The voltage levels of the voltages V1 to V4 correspond to a plurality of discrete voltage levels that can be supplied to the power supply modulators 30A and 30B by the switched-capacitor circuit 20.

However, it is noted that the voltage ratio V1:V2:V3:V4 is not limited to 1:2:3:4. For example, the voltage ratio V1:V2:V3:V4 may be 1:2:4:8 in an alternative aspect.

The configuration of the switched-capacitor circuit 20 illustrated in FIG. 3A is illustrative and is not restrictive. In FIG. 3A, the switched-capacitor circuit 20 is configured to supply voltages of four discrete voltage levels, but the configuration is not limited thereto. The switched-capacitor circuit 20 may be configured to supply voltages of any number of two or more discrete voltage levels. For example, in the case of supplying voltages of two discrete voltage levels, it is sufficient that the switched-capacitor circuit 20 include at least the capacitors C12 and C15 and the switches S21 to S24 and S31 to S34.

### [1.2.2. Circuit Configurations of Supply Modulators 30A and 30B]

Next, the circuit configurations of the supply modulators 30A and 30B will be described. The supply modulator 30A is an example of a first supply modulator and is connected to the digital control circuit 60. As illustrated in FIG. 3A, the supply modulator 30A includes input terminals 131A to 134A, switches S51A to S54A, and an output terminal 130A. The supply modulator 30B is an example of a second supply modulator and is connected to the digital control circuit 60. As illustrated in FIG. 3A, the supply modulator 30B includes input terminals 131B to 134B, switches S51B to S54B, and an output terminal 130B.

Hereinafter, the supply modulator 30A will be described, and the description of the supply modulator 30B will be basically omitted. The supply modulator 30B is substantially the same as the supply modulator 30A except that a reference sign “B” is used instead of “A”, unless otherwise described.

The output terminal 130A is connected to the filter circuit 40. The output terminal 130A is a terminal for supplying, via the filter circuit 40, the PA 2A with at least one voltage selected from among the voltages V1 to V4 by the supply modulator 30A as the power supply voltage V_{ETA}. As described above, the supply modulator 30A may include various circuit elements and/or wiring lines that cause a voltage drop and/or noise or the like. Thus, the power supply voltage V_{ETA} observed at the output terminal 130A may include a voltage different from the voltages V1 to V4.

The output terminal 130B is an example of a second output terminal, and is a terminal for supplying, without via a filter circuit, the PA 2B with at least one voltage selected from among the voltages V1 to V4 by the supply modulator 30B as the power supply voltage V_{ETB}. As described above, the supply modulator 30B may include various circuit elements and/or wiring lines that cause a voltage drop and/or noise or the like. Thus, the power supply voltage V_{ETB} observed at the output terminal 130B may include a voltage different from the voltages V1 to V4.

The input terminals 131A to 134A are connected to the nodes N4 to N1 of the switched-capacitor circuit 20, respectively. The input terminals 131A to 134A are terminals for receiving the voltages V4 to V1 from the switched-capacitor circuit 20, respectively.

The switch S51A is connected between the input terminal 131A and the output terminal 130A. According to some exemplary aspects, the switch S51A has a terminal connected to the input terminal 131A and a terminal connected to the output terminal 130A. In this connection configuration, ON/OFF switching of the switch S51A by a control signal CS3A enables switching between connection and disconnection between the input terminal 131A and the output terminal 130A.

The switch S52A is connected between the input terminal 132A and the output terminal 130A. According to some exemplary aspects, the switch S52A has a terminal connected to the input terminal 132A and a terminal connected to the output terminal 130A. In this connection configuration, ON/OFF switching of the switch S52A by the control signal CS3A enables switching between connection and disconnection between the input terminal 132A and the output terminal 130A.

The switch S53A is connected between the input terminal 133A and the output terminal 130A. According to some exemplary aspects, the switch S53A has a terminal connected to the input terminal 133A and a terminal connected to the output terminal 130A. In this connection configuration, ON/OFF switching of the switch S53A by the control signal CS3A enables switching between connection and disconnection between the input terminal 133A and the output terminal 130A.

The switch S54A is connected between the input terminal 134A and the output terminal 130A. According to some exemplary aspects, the switch S54A has a terminal connected to the input terminal 134A and a terminal connected to the output terminal 130A. In this connection configuration, ON/OFF switching of the switch S54A by the control signal CS3A enables switching between connection and disconnection between the input terminal 134A and the output terminal 130A.

These switches S51A to S54A are controlled so as to be exclusively turned ON. In other words, only any one of the switches S51A to S54A is turned ON, and the others are turned OFF. Accordingly, the supply modulator 30A is configured to output one voltage selected from among the voltages V1 to V4.

The configuration of the supply modulator 30A illustrated in FIG. 3A is illustrative and is not restrictive. In particular, the switches S51A to S54A may have any configuration as long as any one of the four input terminals 131A to 134A can be selected and connected to the output terminal 130A. For example, the supply modulator 30A may further include a switch connected between a set of the switches S51A to S53A and a set of the switch S54A and the output terminal 130A. For example, the supply modulator 30A may further include a switch connected between a set of the switches S51A and S52A and a set of the switches S53A and S54A and the output terminal 130A.

In a case where voltages of two discrete voltage levels are supplied from the switched-capacitor circuit 20, it is sufficient that the supply modulator 30A include at least two of the switches S51A to S54A.

### [1.2.3. Circuit Configuration of Pre-Regulator Circuit 10]

The configuration of the pre-regulator circuit 10 will be described. As illustrated in FIG. 3A, the pre-regulator circuit 10 includes an input terminal 110, output terminals 111 to 114, inductor connection terminals 115 and 116, switches S61 to S63, S71, and S72, a power inductor L71, and capacitors C61 to C64.

The input terminal 110 is an input terminal for a DC voltage. According to some exemplary aspects, the input terminal 110 is a terminal for receiving an input voltage from the DC power source 50.

The output terminal 111 is an output terminal for the voltage V4. According to some exemplary aspects, the output terminal 111 is a terminal for supplying the voltage V4 to the switched-capacitor circuit 20. The output terminal 111 is connected to the node N4 of the switched-capacitor circuit 20.

The output terminal 112 is an output terminal for the voltage V3. According to some exemplary aspects, the output terminal 112 is a terminal for supplying the voltage V3 to the switched-capacitor circuit 20. The output terminal 112 is connected to the node N3 of the switched-capacitor circuit 20.

The output terminal 113 is an output terminal for the voltage V2. According to some exemplary aspects, the output terminal 113 is a terminal for supplying the voltage V2 to the switched-capacitor circuit 20. The output terminal 113 is connected to the node N2 of the switched-capacitor circuit 20.

The output terminal 114 is an output terminal for the voltage V1. According to some exemplary aspects, the output terminal 114 is a terminal for supplying the voltage V1 to the switched-capacitor circuit 20. The output terminal 114 is connected to the node N1 of the switched-capacitor circuit 20.

The inductor connection terminal 115 is connected to one end of the power inductor L71. The inductor connection terminal 116 is connected to the other end of the power inductor L71.

The switch S71 is connected between the input terminal 110 and the one end of the power inductor L71. According to some exemplary aspects, the switch S71 has a terminal connected to the input terminal 110, and a terminal connected to the one end of the power inductor L71 via the inductor connection terminal 115. In this connection configuration, ON/OFF switching of the switch S71 enables switching between connection and disconnection between the input terminal 110 and the one end of the power inductor L71.

The switch S72 is connected between the one end of the power inductor L71 and ground. According to some exemplary aspects, the switch S72 has a terminal connected to the one end of the power inductor L71 via the inductor connection terminal 115, and a terminal connected to ground. In this connection configuration, ON/OFF switching of the switch S72 enables switching between connection and disconnection between the one end of the power inductor L71 and ground.

The switch S61 is connected between the other end of the power inductor L71 and the output terminal 111. According to some exemplary aspects, the switch S61 has a terminal connected to the other end of the power inductor L71 via the inductor connection terminal 116, and a terminal connected to the output terminal 111. In this connection configuration, ON/OFF switching of the switch S61 enables switching between connection and disconnection between the other end of the power inductor L71 and the output terminal 111.

The switch S62 is connected between the other end of the power inductor L71 and the output terminal 112. According to some exemplary aspects, the switch S62 has a terminal connected to the other end of the power inductor L71 via the inductor connection terminal 116, and a terminal connected to the output terminal 112. In this connection configuration, ON/OFF switching of the switch S62 enables switching between connection and disconnection between the other end of the power inductor L71 and the output terminal 112.

The switch S63 is connected between the other end of the power inductor L71 and the output terminal 113. According to some exemplary aspects, the switch S63 has a terminal connected to the other end of the power inductor L71 via the inductor connection terminal 116, and a terminal connected to the output terminal 113. In this connection configuration, ON/OFF switching of the switch S63 enables switching between connection and disconnection between the other end of the power inductor L71 and the output terminal 113.

One of the two electrodes of the capacitor C61 is connected to the switch S61 and the output terminal 111. The other of the two electrodes of the capacitor C61 is connected to the switch S62, the output terminal 112, and one of the two electrodes of the capacitor C62.

The one of the two electrodes of the capacitor C62 is connected to the switch S62, the output terminal 112, and the other of the two electrodes of the capacitor C61. The other of the two electrodes of the capacitor C62 is connected to a path connecting the switch S63, the output terminal 113, and one of the two electrodes of the capacitor C63.

The one of the two electrodes of the capacitor C63 is connected to the switch S63, the output terminal 113, and the other of the two electrodes of the capacitor C62. The other of the two electrodes of the capacitor C63 is connected to the output terminal 114 and one of the two electrodes of the capacitor C64.

The one of the two electrodes of the capacitor C64 is connected to the output terminal 114 and the other of the two electrodes of the capacitor C63. The other of the two electrodes of the capacitor C64 is connected to ground.

The switches S61 to S63 are controlled so as to be exclusively turned ON. In other words, only any one of the switches S61 to S63 is turned ON, and the others are turned OFF. Turning ON of only any one of the switches S61 to S63 enables the pre-regulator circuit 10 to change the voltage to be supplied to the switched-capacitor circuit 20 at the voltage levels of the voltages V2 to V4.

The pre-regulator circuit 10 configured as described above is configured to supply electric charge to the switched-capacitor circuit 20 via at least one of the output terminals 111 to 113.

In a case where an input voltage is converted into one first voltage, it is sufficient that the pre-regulator circuit 10 include at least the switches S71 and S72 and the power inductor L71.

### [1.2.4. Circuit Configuration of Filter Circuit 40]

Next, the circuit configuration of the filter circuit 40 will be described. The filter circuit 40 includes a low pass filter (LPF). According to some exemplary aspects, as illustrated in FIG. 3A, the filter circuit 40 includes inductors L51 to L53, capacitors C51 and C52, a resistor R51, an input terminal 140, and an output terminal 141.

The input terminal 140 is an input terminal for a voltage selected by the supply modulator 30A. According to some exemplary aspects, the input terminal 140 is a terminal for receiving a voltage selected from among the plurality of voltages V1 to V4.

The output terminal 141 is an example of a first output terminal and is an output terminal for the power supply voltage V_{ETA}. In other words, the output terminal 141 is a terminal for supplying the power supply voltage V_{ETA} to the PA 2A.

The inductors L51 to L53, the capacitors C51 and C52, and the resistor R51 form a pulse shaping network. In the present exemplary embodiment, the pulse shaping network has a low pass response. Accordingly, the filter circuit 40 is configured to reduce RF components included in the power supply voltage.

The configuration of the filter circuit 40 illustrated in FIG. 3A is illustrative and is not restrictive. For example, the filter circuit 40 does not necessarily have to include the inductor L53 or the resistor R51. For example, the filter circuit 40 may include an inductor connected to one of the two electrodes of the capacitor C51 and may include an inductor connected to one of the two electrodes of the capacitor C52. The filter circuit 40 may be partially or entirely composed of a parasitic reactance and/or a parasitic resistance. The parasitic reactance includes, for example, the inductance and/or the capacitance of a metal trace connecting two nodes. The parasitic resistance includes, for example, the resistance of a metal trace connecting two nodes.

### [1.2.5. Circuit Configuration of Digital Control Circuit 60]

Next, the circuit configuration of the digital control circuit 60 will be described. As illustrated in FIG. 3B, the digital control circuit 60 includes a first controller 61, a second controller 62, and control terminals 601 to 606.

The first controller 61 is configured to process source-synchronous digital control signals to generate control signals CS1 and CS2. The control signal CS1 is a signal for controlling ON/OFF of the switches S61 to S63, S71, and S72 included in the pre-regulator circuit 10. The control signal CS2 is a signal for controlling ON/OFF of the switches S11 to S14, S21 to S24, S31 to S34, and S41 to S44 included in the switched-capacitor circuit 20. A feedback signal for controlling the switches S61 to S63, S71, and S72 of the pre-regulator circuit 10 is input to the first controller 61.

The digital control signals processed by the first controller 61 are not limited to source-synchronous digital control signals. For example, the first controller 61 may process clock-embedded digital control signals. The first controller 61 may generate a control signal for controlling the supply modulators 30A and 30B.

In the present exemplary embodiment, one set of a clock signal and a data signal is used as digital control signals for the pre-regulator circuit 10 and the switched-capacitor circuit 20, but the digital control signals are not limited thereto. For example, sets of a clock signal and a data signal may be individually used as digital control signals for the pre-regulator circuit 10 and the switched-capacitor circuit 20.

The second controller 62 processes digitally controlled level (DCL) signals (DCL1A and DCL2A) received from the RFIC 5A via the control terminals 603 and 604, thereby generating a control signal CS3A. The DCL signals (DCL1A and DCL2A) are an example of at least one first DCL signal and are generated based on an envelope signal of the RF signal S1 by the RFIC 5A. The control signal CS3A is a signal for controlling ON/OFF of the switches S51A to S54A included in the supply modulator 30A.

Furthermore, the second controller 62 processes DCL signals (DCL1B and DCL2B) received from the RFIC 5B via the control terminals 605 and 606, thereby generating a control signal CS3B. The DCL signals (DCL1B and DCL2B) are an example of at least one second DCL signal and are generated based on an envelope signal of the RF signal S2 by the RFIC 5B. The control signal CS3B is a signal for controlling ON/OFF of the switches S51B to S54B included in the supply modulator 30B.

The DCL signals (DCL1A, DCL2A, DCL1B, and DCL2B) are each a 1-bit signal. Each of the voltages V1 to V4 is represented by a combination of two 1-bit signals. For example, V1, V2, V3, and V4 are represented by “00”, “01”, “10”, and “11”, respectively. A gray code may be used to express a voltage level.

In the present exemplary embodiment, two DCL signals are used to control the supply modulator 30A, and two DCL signals are used to control the supply modulator 30B, but the number of DCL signals is not limited thereto. For example, one or any number of three or more DCL signals may be used in accordance with the number of voltage levels selectable by each of the supply modulators 30A and 30B. The digital control signals used to control the supply modulators 30A and 30B are not limited to DCL signals.

### [1.3. Power Supply Voltage Supply Method]

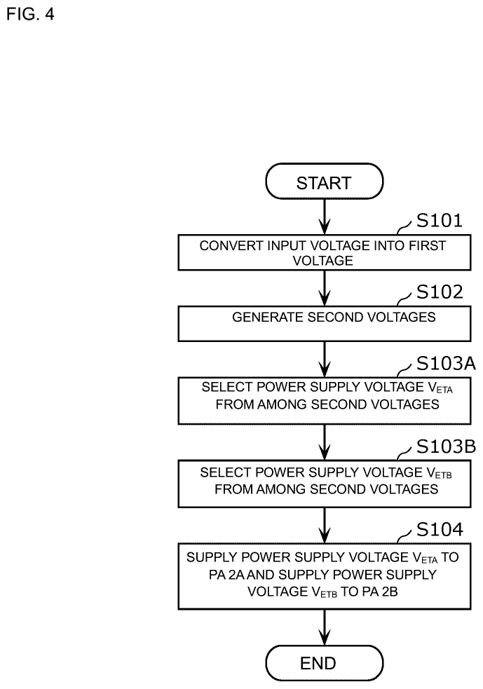

Next, a description will be given of a method for supplying power supply voltages to the two PAs 2A and 2B by the power supply circuit 1 having the above-described configuration, with reference to FIG. 4. FIG. 4 is a flowchart illustrating the power supply voltage supply method according to the present exemplary embodiment.

First, the pre-regulator circuit 10 converts an input voltage received from the DC power source 50 into a first voltage (S101). The switched-capacitor circuit 20 generates, from the first voltage, a plurality of second voltages each having a corresponding one of a plurality of discrete voltage levels (S102). The supply modulator 30A selects, based on an envelope signal of the RF signal S1, at least one of the plurality of second voltages as the power supply voltage V_{ETA} (S103A). That is, the supply modulator 30A controls an output voltage, based on the envelope signal of the RF signal S1. The supply modulator 30B selects, based on an envelope signal of the RF signal S2, at least one of the plurality of second voltages as the power supply voltage V_{ETB} (S103B). That is, the supply modulator 30B controls an output voltage, based on the envelope signal of the RF signal S2. The power supply circuit 1 supplies the power supply voltage V_{ETA} selected by the supply modulator 30A to the PA 2A and supplies the power supply voltage V_{ETB} selected by the supply modulator 30B to the PA 2B (S104).

In FIG. 4, one or some of the plurality of steps may be omitted. For example, step S101 may be omitted. In addition, the order of the steps may be changed. For example, the order of steps S103A and S103B may be reversed. Alternatively, steps S103A and S103B may be performed simultaneously.

An example of packaging of the communication device 7 having the above-described configuration will be described below.

### [1.4. Disposition of Modules]

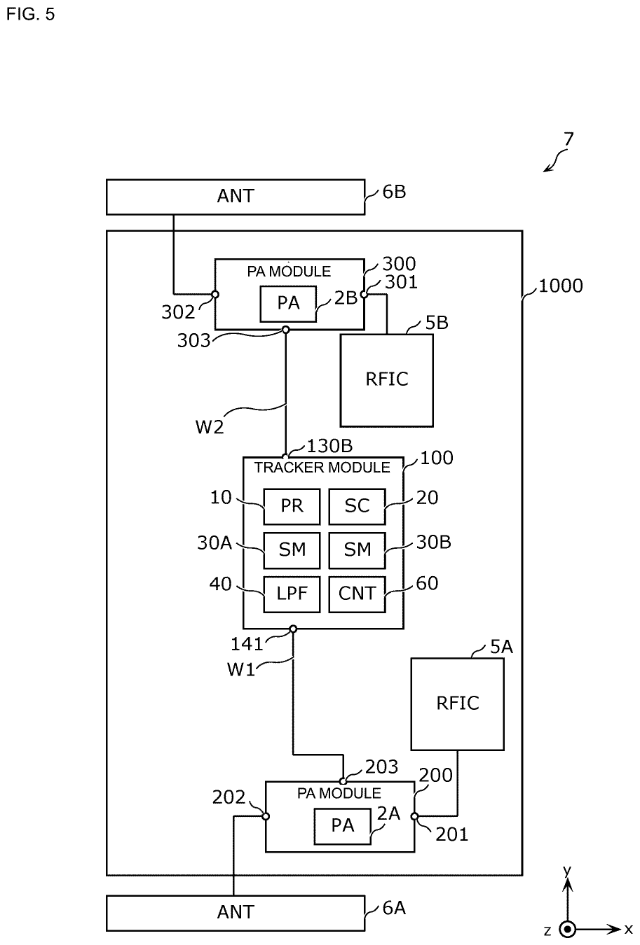

First, the disposition of a tracker module 100, PA modules 200 and 300, and so forth on a mother substrate 1000 of the communication device 7 will be described with reference to FIG. 5. FIG. 5 is a layout diagram of the modules on the mother substrate 1000 according to the present exemplary embodiment.

The tracker module 100 is configured to supply the power supply voltages V_{ETA} and V_{ETB} to the PA modules 200 and 300, respectively, and includes the pre-regulator circuit 10 (PR), the switched-capacitor circuit 20 (SC), the supply modulators 30A and 30B (SM), the filter circuit 40 (LPF), and the digital control circuit 60 (CNT). The tracker module 100 is disposed between the PA modules 200 and 300 on the mother substrate 1000.

The PA module 200 includes the PA 2A configured to amplify a Sub6 signal of a cellular network. The power supply terminal 203 of the PA module 200 is connected to the output terminal 141 of the tracker module 100 via a wiring line W1.

The PA module 300 includes the PA 2B configured to amplify a 2.4 GHz band signal of a WLAN. The power supply terminal 303 of the PA module 300 is connected to the output terminal 130B of the tracker module 100 via a wiring line W2. Here, the length of the wiring line W2 may be shorter than the length of the wiring line W1. Furthermore, the width of the wiring line W2 may be larger than the width of the wiring line W1.

The length of a wiring line means a length, in a direction in which a current flows, of a conductor that electrically connects two terminals. The width of a wiring line means a length in a direction orthogonal to the direction in which a current flows in plan view of the substrate.

The RFIC 5A is disposed near the PA module 200. According to some exemplary aspects, the RFIC 5A is disposed closer to the PA module 200 than to the PA module 300.

The RFIC 5B is disposed near the PA module 300. According to some exemplary aspects, the RFIC 5B is disposed closer to the PA module 300 than to the PA module 200.

The antenna 6A is disposed adjacent to a lower side of the mother substrate 1000 and is disposed near the PA module 200. The antenna 6B is disposed adjacent to an upper side of the mother substrate 1000 and is disposed near the PA module 300.

### [1.5. Configuration of Tracker Module 100]

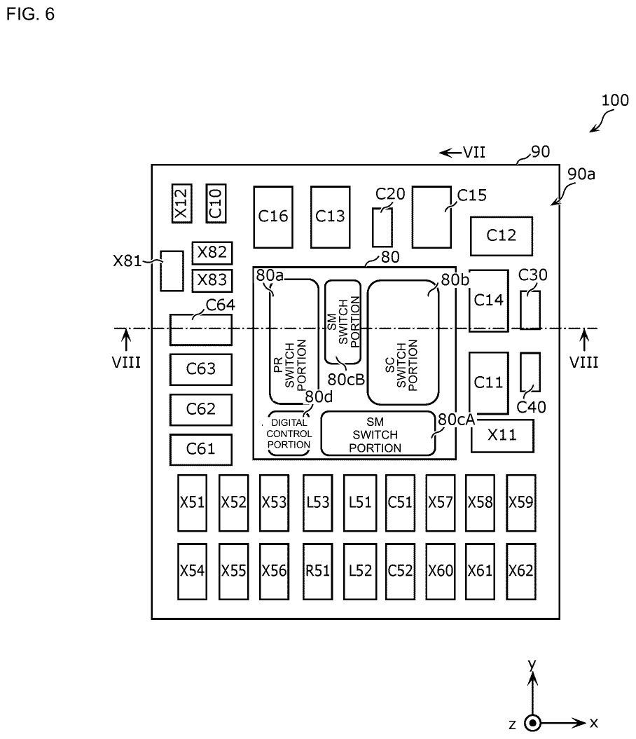

Next, the configuration of the tracker module 100 will be described with reference to FIG. 6 to FIG. 8. In the present exemplary embodiment, the power inductor L71 included in the pre-regulator circuit 10 is not disposed on or in a module laminate 90 and is not included in the tracker module 100, but the present disclosure is not limited thereto.

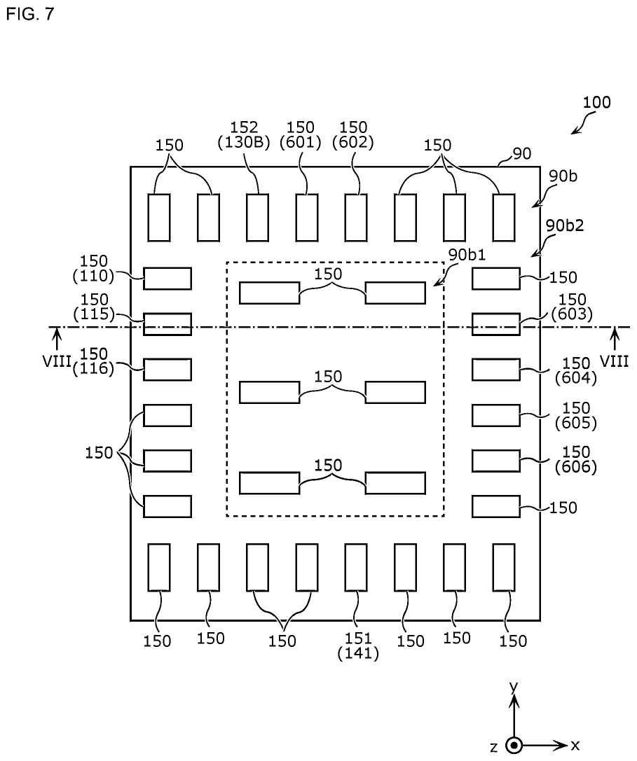

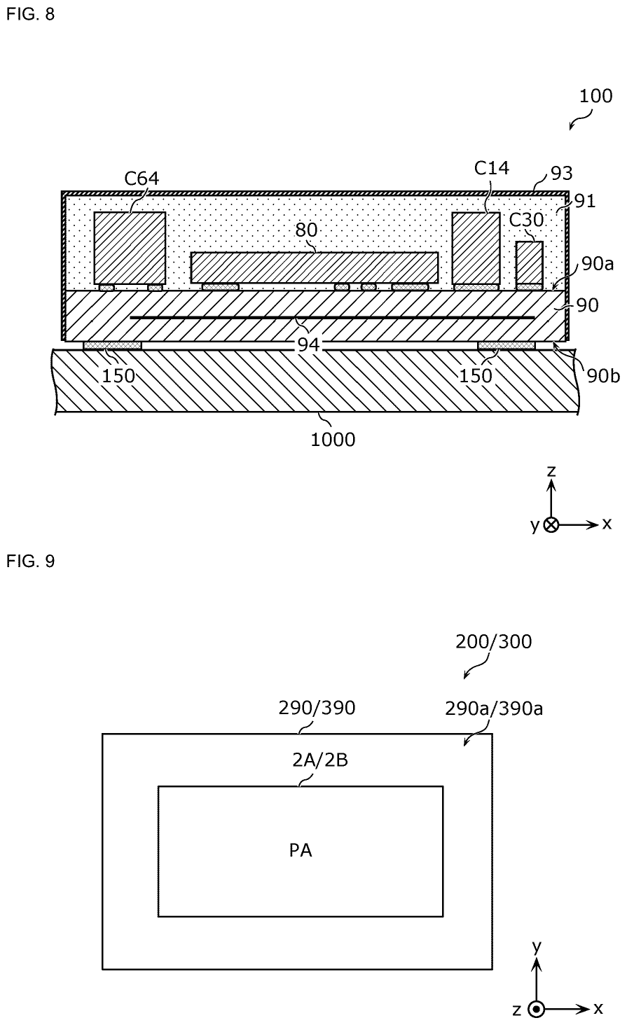

FIG. 6 is a plan view of the tracker module 100 according to the present exemplary embodiment. FIG. 7 is a plan view of the tracker module 100 according to the present exemplary embodiment, in which a main surface 90b side of the module laminate 90 is seen through from the positive side of the z-axis. FIG. 8 is a sectional view of the tracker module 100 according to the present exemplary embodiment. The section of the tracker module 100 in FIG. 8 is a section taken along the VIII-VIII line in FIG. 6 and FIG. 7.

In FIG. 6 to FIG. 8, the illustration of wiring lines connecting a plurality of circuit components disposed on or in the module laminate 90 is partially omitted. In FIG. 6 and FIG. 7, the illustration of a resin member 91 covering the plurality of circuit components and a shield electrode layer 93 covering the surface of the resin member 91 is omitted.

The tracker module 100 includes the module laminate 90, the resin member 91, the shield electrode layer 93, circuit components X11, X12, X51 to X62, and X81 to X83, and a plurality of land electrodes 150, in addition to the plurality of circuit components including the active elements and passive elements included in the pre-regulator circuit 10, the switched-capacitor circuit 20, the supply modulators 30A and 30B, the filter circuit 40, and the digital control circuit 60 (except for the power inductor L71) illustrated in FIG. 3A and FIG. 3B.

The module laminate 90 has a main surface 90a and the main surface 90b opposed to each other. The module laminate 90 includes a wiring layer, via-conductors, a ground plane 94, and so forth formed therein. In FIG. 6 and FIG. 7, the module laminate 90 has a rectangular shape in plan view, but the shape is not limited thereto.

The module laminate 90 may be, but is not limited to, a low temperature co-fired ceramics (LTCC) substrate or a high temperature co-fired ceramics (HTCC) substrate having a multilayer structure of a plurality of dielectric layers, a component-embedded board, a substrate including a redistribution layer (RDL), a printed circuit board, or the like, for example.

On the main surface 90a, there are disposed an integrated circuit 80; the capacitors C10 to C16, C20, C30, C40, C51, C52, and C61 to C64; the inductors L51 to L53; the resistor R51; the circuit components X11, X12, X51 to X62, and X81 to X83; and the resin member 91.

The integrated circuit 80 includes a PR switch portion 80a, an SC switch portion 80b, SM switch portions 80cA and 80cB, and a digital control portion 80d. The PR switch portion 80a includes the switches S61 to S63, S71, and S72. The SC switch portion 80b includes the switches S11 to S14, S21 to S24, S31 to S34, and S41 to S44. The SM switch portion 80cA includes the switches S51A to S54A. The SM switch portion 80cB includes the switches S51B to S54B. The digital control portion 80d includes the first controller 61 and the second controller 62.

In FIG. 6, the PR switch portion 80a, the SC switch portion 80b, the SM switch portions 80cA and 80cB, and the digital control portion 80d are included in the single integrated circuit 80, but the configuration is not limited thereto. For example, the PR switch portion 80a and the SC switch portion 80b may be included in an integrated circuit, and the SM switch portions 80cA and 80cB may be included in another integrated circuit. Alternatively, for example, the SC switch portion 80b and the SM switch portions 80cA and 80cB may be included in an integrated circuit, and the PR switch portion 80a may be included in another integrated circuit. Alternatively, the PR switch portion 80a and the SM switch portions 80cA and 80cB may be included in an integrated circuit, and the SC switch portion 80b may be included in another integrated circuit. Alternatively, for example, the PR switch portion 80a, the SC switch portion 80b, and the SM switch portions 80cA and 80cB may be included in three respective integrated circuits. In this case, the digital control portion 80d may be included in each of the plurality of integrated circuits or may be included in only one of the plurality of integrated circuits. The plurality of integrated circuits can be manufactured by different process technology nodes.

In FIG. 6, the integrated circuit 80 has a rectangular shape in plan view of the module laminate 90, but the shape is not limited thereto.

The integrated circuit 80 is formed by using, for example, complementary metal oxide semiconductor (CMOS), and According to some exemplary aspects may be manufactured by a silicon on insulator (SOI) process. The integrated circuit 80 is not limited to CMOS.

In an exemplary aspect, the capacitors C10 to C16, C20, C30, C40, C51, C52, and C61 to C64 are each implemented as a chip capacitor. The chip capacitor can be a surface mount device (SMD) forming a capacitor. It is noted that the implementation of the plurality of capacitors is not limited to chip capacitors. For example, some or all of the plurality of capacitors may be included in an integrated passive device (IPD) or may be included in the integrated circuit 80.

In an exemplary aspect, the inductors L51 to L53 are each implemented as a chip inductor. The chip inductor can be an SMD forming an inductor. It is noted that the implementation of the plurality of inductors is not limited to chip inductors. For example, the plurality of inductors may be included in an IPD.

In an exemplary aspect, the resistor R51 is implemented as a chip resistor. The chip resistor can be an SMD forming a resistor. The implementation of the resistor R51 is not limited to a chip resistor. For example, the resistor R51 may be included in an IPD.

In this way, the plurality of capacitors, the plurality of inductors, and the resistor disposed on the main surface 90a are grouped for the individual circuits and disposed around the integrated circuit 80.

A group of the capacitors C61 to C64 included in the pre-regulator circuit 10 is disposed in a region on the main surface 90a sandwiched between a straight line along the left side of the integrated circuit 80 and a straight line along the left side of the module laminate 90 in plan view of the module laminate 90. Accordingly, a group of the circuit components included in the pre-regulator circuit 10 is disposed close to the PR switch portion 80a in the integrated circuit 80.

A group of the capacitors C10 to C16, C20, C30, and C40 included in the switched-capacitor circuit 20 is disposed in a region on the main surface 90a sandwiched between a straight line along the upper side of the integrated circuit 80 and a straight line along the upper side of the module laminate 90, and a region on the main surface 90a sandwiched between a straight line along the right side of the integrated circuit 80 and a straight line along the right side of the module laminate 90, in plan view of the module laminate 90. Accordingly, a group of the circuit components included in the switched-capacitor circuit 20 is disposed close to the SC switch portion 80b in the integrated circuit 80. That is, the SC switch portion 80b is disposed closer to the switched-capacitor circuit 20 than each of the PR switch portion 80a and the SM switch portion 80cA.

A group of the capacitors C51 and C52, the inductors L51 to L53, and the resistor R51 included in the filter circuit 40 is disposed in a region on the main surface 90a sandwiched between a straight line along the lower side of the integrated circuit 80 and a straight line along the lower side of the module laminate 90 in plan view of the module laminate 90. Accordingly, a group of the circuit components included in the filter circuit 40 is disposed close to the SM switch portion 80cA in the integrated circuit 80. That is, the SM switch portion 80cA is disposed closer to the filter circuit 40 than each of the PR switch portion 80a and the SC switch portion 80b.

According to an exemplary aspect, the circuit components X11, X12, X51 to X62, and X81 to X83 are optional circuit components that are not in the tracker module 100 in some exemplary embodiments.

The resin member 91 covers the main surface 90a and at least a part of the plurality of electronic components on the main surface 90a. The resin member 91 has a function of ensuring reliability, such as mechanical strength and moisture resistance, of the plurality of electronic components on the main surface 90a. The resin member 91 does not necessarily have to be included in the tracker module 100.

The plurality of land electrodes 150 are disposed on the main surface 90b. The plurality of land electrodes 150 function as a plurality of external connection terminals including ground terminals in addition to the input terminal 110, the output terminals 130B and 141, the inductor connection terminals 115 and 116, and the control terminals 601 to 606 illustrated in FIG. 3A and FIG. 3B.

The plurality of land electrodes 150 are electrically connected to input and output terminals and/or ground terminals on the mother substrate 1000 disposed in the z-axis negative direction of the tracker module 100. In addition, the plurality of land electrodes 150 are electrically connected to the plurality of circuit components disposed on the main surface 90a via the via-conductors or the like formed in the module laminate 90.

The plurality of land electrodes 150 may be, but are not limited to, copper electrodes. For example, the plurality of land electrodes 150 may be solder electrodes. Instead of the plurality of land electrodes 150, a plurality of bump electrodes or a plurality of post electrodes may be used as the plurality of external connection terminals.

In FIG. 7, the plurality of land electrodes 150 include, in plan view of the module laminate 90, twenty-eight land electrodes 150 disposed in a peripheral region 90b2 surrounding a central region 90b1 of the module laminate 90, and six land electrodes 150 disposed in the central region 90b1 of the module laminate 90. The twenty-eight land electrodes 150 disposed in the peripheral region 90b2 include a land electrode 151 functioning as the output terminal 141 and a land electrode 152 functioning as the output terminal 130B. The land electrodes 151 and 152 are disposed along sides opposed to each other in plan view of the module laminate 90. In FIG. 7, the land electrode 151 is disposed along the lower side (an example of a first side) of the module laminate 90, and the land electrode 152 is disposed along the upper side (an example of a second side) of the module laminate 90. In other words, the land electrode 151 is disposed in a region along the lower side of the module laminate 90 in the peripheral region 90b2, and the land electrode 152 is disposed in a region along the upper side of the module laminate 90 in the peripheral region 90b2.

The shield electrode layer 93 is a metal thin film formed by sputtering, for example. The shield electrode layer 93 is formed so as to cover the surfaces (upper surface and side surfaces) of the resin member 91. The shield electrode layer 93 is connected to ground and reduces entry of external noise into the electronic components forming the tracker module 100 and interference of noise generated in the tracker module 100 with another module or another device. The shield electrode layer 93 does not necessarily have to be included in the tracker module 100.

The configuration of the tracker module 100 according to the present exemplary embodiment is illustrative and is not restrictive. For example, one or some of the capacitors and inductors disposed on the main surface 90a may be formed in the module laminate 90. In addition, one or some of the capacitors and inductors disposed on the main surface 90a do not necessarily have to be included in the tracker module 100, and do not necessarily have to be disposed on or in the module laminate 90.

The positional relationship between the land electrode 151 functioning as the output terminal 141 and the land electrode 152 functioning as the output terminal 130B is an example and may be changed as appropriate in accordance with the positional relationship between the tracker module 100 and the PA modules 200 and 300. For example, the land electrodes 151 and 152 may be disposed along the same side. Alternatively, for example, the land electrodes 151 and 152 may be disposed along two sides orthogonal to each other.

### [1.6. Configurations of PA Modules 200 and 300]

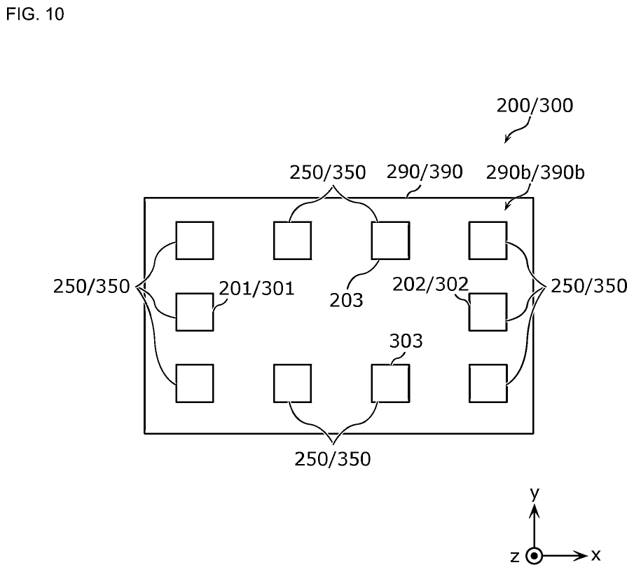

Next, the configurations of the PA modules 200 and 300 will be described with reference to FIG. 9 and FIG. 10. The PA modules 200 and 300 have similar configurations, and thus the description of the PA module 300 is omitted regarding the same configuration.

FIG. 9 is a plan view of the PA modules 200 and 300 according to the present exemplary embodiment. FIG. 10 is a plan view of the PA modules 200 and 300 according to the present exemplary embodiment, in which a main surface 290b side of a module laminate 290 and a main surface 390b side of a module laminate 390 are seen through from the positive side of the z-axis.

In FIG. 9 and FIG. 10, the illustration of wiring lines connecting the plurality of circuit components disposed on or in the module laminates 290 and 390 is omitted. In FIG. 9 and FIG. 10, the illustration of a resin member covering the plurality of circuit components and a shield electrode layer covering the surface of the resin member is omitted.

The PA module 200 includes the module laminate 290 and a plurality of land electrodes 250 in addition to the PA 2A.

The module laminate 290 has a main surface 290a and the main surface 290b opposed to each other. The module laminate 290 includes a wiring layer, via-conductors, a ground plane, and so forth formed therein. In FIG. 9 and FIG. 10, the module laminate 290 has a rectangular shape in plan view, but the shape is not limited thereto.

The module laminate 290 may be, but is not limited to, an LTCC substrate or an HTCC substrate having a multilayer structure of a plurality of dielectric layers, a component-embedded board, a substrate having an RDL, a printed circuit board, or the like, for example.

The PA 2A is disposed on the main surface 290a. The PA 2A is mounted in, for example, an integrated circuit. In this case, the integrated circuit may be composed of at least one of silicon (Si), gallium arsenide (GaAs), silicon germanium (SiGe), and gallium nitride (GaN), but the material of the integrated circuit is not limited thereto.

The plurality of land electrodes 250 are disposed on the main surface 290b. The plurality of land electrodes 250 function as a plurality of external connection terminals including ground terminals in addition to the input terminal 201, the output terminal 202, and the power supply terminal 203 illustrated in FIG. 5.

The plurality of land electrodes 250 are electrically connected to input and output terminals and/or ground terminals on the mother substrate 1000 disposed in the z-axis negative direction of the PA module 200. In addition, the plurality of land electrodes 250 are electrically connected to the PA 2A disposed on the main surface 290a via the via-conductors or the like formed in the module laminate 290.

The plurality of land electrodes 250 may be, but are not limited to, copper electrodes. For example, the plurality of land electrodes 250 may be solder electrodes. Instead of the plurality of land electrodes 250, a plurality of bump electrodes or a plurality of post electrodes may be used as the plurality of external connection terminals.

The configurations of the PA modules 200 and 300 according to the present exemplary embodiment are illustrative, and are not restrictive.

### [1.7. Advantageous Effects and the Like]

As described above, the power supply circuit 1 according to the present exemplary embodiment includes the switched-capacitor circuit 20 configured to generate, based on an input voltage, a plurality of discrete voltages; the supply modulator 30A configured to selectively output, based on an envelope signal of the RF signal S1, at least one of the plurality of discrete voltages to the PA 2A; and the supply modulator 30B configured to selectively output, based on an envelope signal of the RF signal S2, at least one of the plurality of discrete voltages to the PA 2B. The PA 2A is configured to amplify the RF signal S1. The PA 2B is configured to amplify the RF signal S2. The RF signal S1 is a Sub6 signal of a cellular network. The RF signal S2 is a 2.4 GHz band signal of a WLAN.

Accordingly, at least one voltage selected from among the plurality of discrete voltages based on the envelope signal of the WLAN signal is supplied as the power supply voltage V_{ETB} to the PA 2B. In general, a WLAN signal has a large band width, and thus the change rate of amplitude variation of the envelope signal is high (i.e., the envelope signal changes fast). Thus, for amplification of the WLAN signal, it is difficult to use the analog ET mode, and the APT mode or a fixed voltage mode is often used. Use of the digital ET mode for amplification of such a WLAN signal makes it possible to improve PAE. Furthermore, according to the present exemplary embodiment, the digital ET mode is applied to both the PA 2A that amplifies a cellular network signal and the PA 2B that amplifies a WLAN signal. Thus, the switched-capacitor circuit 20 that generates a plurality of discrete voltages can be shared between the PAs 2A and 2B, which contributes to a decreased size of the power supply circuit 1 (i.e., a decreased area occupied by the power supply circuit 1) compared with a case where the analog ET mode, in which voltage generators are necessary for individual PAs, is applied to the PAs 2A and 2B.

For example, in the power supply circuit 1 according to the present exemplary embodiment, the switched-capacitor circuit 20 and the supply modulators 30A and 30B may be mounted on or in the module laminate 90. The module laminate 90 may include the output terminal 141 connected to the PA 2A and the output terminal 130B connected to the PA 2B. The output terminal 141 may be disposed along the lower side of the module laminate 90. The output terminal 130B may be disposed along the upper side opposed to the lower side of the module laminate 90.

Accordingly, the output terminals 141 and 130B connected to the two PAs 2A and 2B, respectively, are disposed along the sides opposed to each other of the module laminate 90. Thus, the flexibility of the disposition of the PAs 2A and 2B and the power supply circuit 1 can be increased, and the lengths of the wiring lines for connecting the PAs 2A and 2B to the power supply circuit 1 can be easily shortened.

For example, in the power supply circuit 1 according to the present exemplary embodiment, the module laminate 90 may be disposed between the PAs 2A and 2B.

Accordingly, the lengths of the wiring lines for connecting the output terminals 141 and 130B to the PAs 2A and 2B, respectively, can be shortened, and deterioration of a power supply voltage signal resulting from a parasitic capacitance and/or a parasitic inductance can be reduced.

For example, in the power supply circuit 1 according to the present exemplary embodiment, the switched-capacitor circuit 20 and the supply modulators 30A and 30B may be mounted on or in the module laminate 90. The module laminate 90 may include the output terminal 141 connected to the PA 2A and the output terminal 130B connected to the PA 2B. The output terminals 141 and 130B may be disposed along the same side of the module laminate 90.

Accordingly, in a case where the PAs 2A and 2B are disposed in similar directions with respect to the module laminate 90, for example, the lengths of the wiring lines for connecting the power supply circuit 1 to the PAs 2A and 2B can be easily shortened.

For example, in the power supply circuit 1 according to the present exemplary embodiment, the RF signal S1 may be a transmission signal of FDD. The power supply circuit 1 may further include the filter circuit 40 connected to the supply modulator 30A. The supply modulator 30A may output the power supply voltage V_{ETA} to the PA 2A via the filter circuit 40.

Accordingly, the power supply voltage V_{ETA} is supplied to the PA 2A via the filter circuit 40, which makes it possible to reduce a decrease in the reception sensitivity of a reception signal of FDD resulting from noise included in the signal of the power supply voltage V_{ETA}.

For example, in the power supply circuit 1 according to the present exemplary embodiment, the filter circuit 40 may be mounted on or in the module laminate 90.

This contributes to a decreased size of the communication device 7.

For example, the power supply circuit 1 according to the present exemplary embodiment may further include the pre-regulator circuit 10 that converts the input voltage by using the power inductor L71.

Accordingly, variations in the input voltage of the switched-capacitor circuit 20 resulting from voltage variations of the DC power source 50 can be reduced, and the stability of the voltage levels of the plurality of discrete voltages generated by the switched-capacitor circuit 20 can be increased.

The power supply voltage supply method according to the present exemplary embodiment includes generating, based on an input voltage, a plurality of discrete voltages; selecting, based on an envelope signal of the RF signal S1, at least one of the plurality of second voltages as the power supply voltage V_{ETA}; supplying the selected power supply voltage V_{ETA} to the PA 2A configured to amplify the RF signal S1; selecting, based on an envelope signal of the RF signal S2, at least one of the plurality of discrete voltages as the power supply voltage V_{ETB}; and supplying the selected power supply voltage V_{ETB} to the PA 2B configured to amplify the RF signal S2. The RF signal S1 is a cellular network signal. The RF signal S2 is a WLAN signal.

Accordingly, advantageous effects similar to those of the above-described power supply circuit 1 can be obtained.

For example, the power supply voltage supply method according to the present exemplary embodiment may further include generating, based on the envelope signal of the RF signal S1, a first DCL signal (DCL1A and DCL2A); and generating, based on the envelope signal of the RF signal S2, a second DCL signal (DCL1B and DCL2B). The power supply voltage V_{ETA} may be selected based on the first DCL signal. The power supply voltage V_{ETB} may be selected based on the second DCL signal.

Accordingly, a power supply voltage can be selected, based on the DCL signal generated based on the envelope signal, from among the plurality of second voltages.

In the present exemplary embodiment, a 2.4 GHz band signal of a WLAN is used as the RF signal S2, but the RF signal S2 is not limited thereto. For example, a 5 GHz band signal of a WLAN may be used as the RF signal S2.

### Second Exemplary Embodiment

Next, a second embodiment will be described. The present exemplary embodiment is different from the above-described first embodiment mainly in that the PA 2B is configured to amplify a 5 GHz band signal of a WLAN and that the supply modulator 30B is not included in the tracker module but is included in an SW module. Hereinafter, the present exemplary embodiment will be described with a focus on differences from the above-described first embodiment.

The circuit configurations of the communication device 7 and the power supply circuit 1 and the power supply voltage supply method according to the present exemplary embodiment are similar to those of the above-described first embodiment, and thus the description thereof is omitted.

### [2.1. Disposition of Modules]

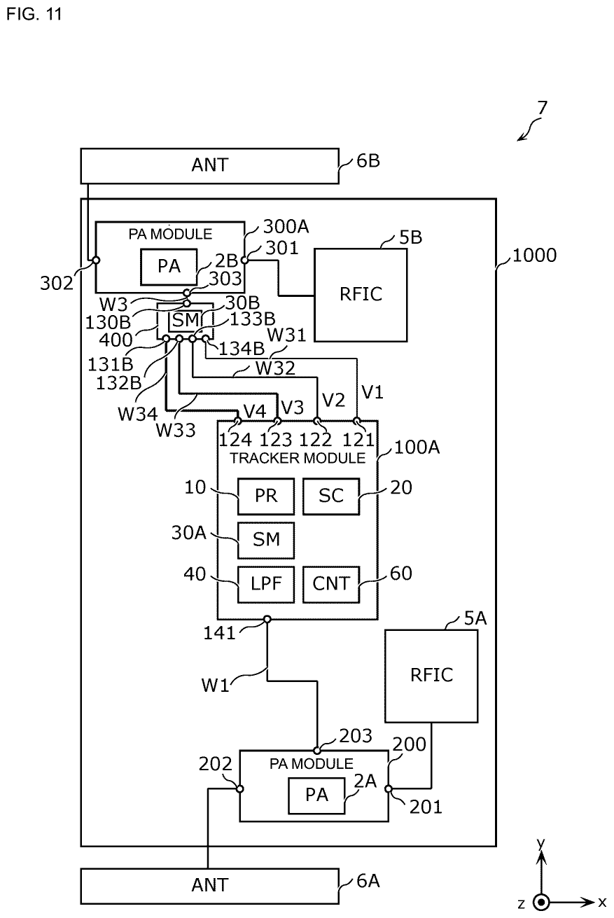

The disposition of a tracker module 100A, the PA module 200, a PA module 300A, an integrated circuit 400, and so forth on the mother substrate 1000 of the communication device 7 will be described with reference to FIG. 11. FIG. 11 is a layout diagram of the modules on the mother substrate 1000 according to the present exemplary embodiment.

The tracker module 100A includes the pre-regulator circuit 10 (PR), the switched-capacitor circuit 20 (SC), the supply modulator 30A (SM), the filter circuit 40 (LPF), and the digital control circuit 60 (CNT). The tracker module 100A is disposed between the PA modules 200 and 300A on the mother substrate 1000. The tracker module 100A has output terminals 121 to 124 that are connected to the nodes N1 to N4 of the switched-capacitor circuit 20, respectively, and that are for supplying the voltages V1 to V4, respectively. With this configuration, the tracker module 100A is configured to supply the power supply voltage V_{ETA} to the PA module 200 via the output terminal 141 and applying the plurality of voltages V1 to V4 to the integrated circuit 400 via the output terminals 121 to 124 (i.e., without via a supply modulator).

The PA module 300A includes the PA 2B configured to amplify a 5 GHz band signal of a WLAN. The power supply terminal 303 of the PA module 300A is connected to the output terminal 130B of the integrated circuit 400 via a wiring line W3. Accordingly, the PA module 300A is configured to receive the power supply voltage V_{ETB} from the integrated circuit 400.

The integrated circuit 400 includes the supply modulator 30B and is disposed between the tracker module 100A and the PA module 300A on the mother substrate 1000. The integrated circuit 400 is an integrated circuit formed by using, for example, CMOS, and is disposed on or in the mother substrate 1000. The integrated circuit 400 may be manufactured by an SOI process, for example. The integrated circuit 400 is not limited to CMOS.

The integrated circuit 400 is connected to the tracker module 100A via wiring lines W31 to W34. According to some exemplary aspects, the input terminal 131B is connected to the output terminal 124 of the tracker module 100A via the wiring line W34. The input terminal 132B is connected to the output terminal 123 of the tracker module 100A via the wiring line W33. The input terminal 133B is connected to the output terminal 122 of the tracker module 100A via the wiring line W32. The input terminal 134B is connected to the output terminal 121 of the tracker module 100A via the wiring line W31. Accordingly, the voltages V4 to V1 are applied from the switched-capacitor circuit 20 to the input terminals 131B to 134B, respectively. The length of the wiring line W34 may be shorter than the length of the wiring line W31, and the width of the wiring line W34 may be larger than the width of the wiring line W31.

### [2.2. Configuration of Tracker Module 100A]

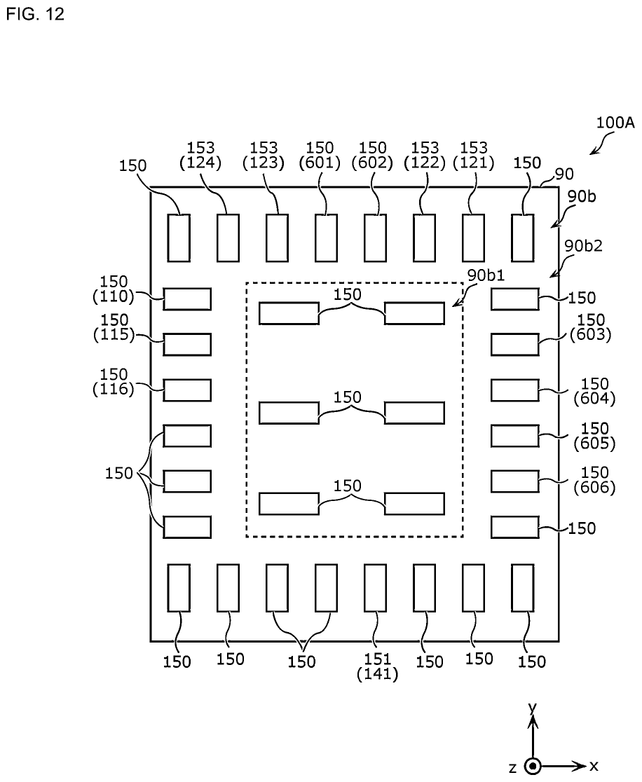

Next, the configuration of the tracker module 100A will be described with reference to FIG. 12. Here, the disposition of the plurality of land electrodes 150 disposed on the main surface 90b of the module laminate 90 will be described with reference to FIG. 12.

FIG. 12 is a plan view of the tracker module 100A according to the present exemplary embodiment, in which the main surface 90b side of the module laminate 90 is seen through from the positive side of the z-axis. The plurality of land electrodes 150 are disposed on the main surface 90b. The plurality of land electrodes 150 function as a plurality of external connection terminals including ground terminals in addition to the input terminal 110, the output terminals 121 to 124 and 141, the inductor connection terminals 115 and 116, and the control terminals 601 to 606.

In FIG. 12, the plurality of land electrodes 150 include, in plan view of the module laminate 90, twenty-eight land electrodes 150 disposed in the peripheral region 90b2 surrounding the central region 90b1 of the module laminate 90, and six land electrodes 150 disposed in the central region 90b1 of the module laminate 90. The twenty-eight land electrodes 150 disposed in the peripheral region 90b2 include the land electrode 151 functioning as the output terminal 141 and four land electrodes 153 functioning as the output terminals 121 to 124. The land electrode 151 and the land electrodes 153 are disposed along sides opposed to each other in plan view of the module laminate 90. In FIG. 12, the land electrode 151 is disposed along the lower side of the module laminate 90, and the land electrodes 153 are disposed along the upper side of the module laminate 90. In other words, the land electrode 151 is disposed in a region along the lower side of the module laminate 90 in the peripheral region 90b2, and the land electrodes 153 are disposed in a region along the upper side of the module laminate 90 in the peripheral region 90b2.

The configuration of the tracker module 100A according to the present exemplary embodiment is illustrative and is not restrictive. For example, the positional relationship between the land electrode 151 functioning as the output terminal 141 and the land electrodes 153 functioning as the output terminals 121 to 124 is an example and may be changed as appropriate in accordance with the positional relationship between the tracker module 100A and the PA modules 200 and 300A. For example, the land electrode 151 and the land electrodes 153 may be disposed along the same side. Alternatively, for example, the land electrode 151 and the land electrodes 153 may be disposed along two sides orthogonal to each other.

### [2.3. Advantageous Effects and the Like]

As described above, the power supply circuit 1 according to the present exemplary embodiment includes the switched-capacitor circuit 20 configured to generate, based on an input voltage, a plurality of discrete voltages; the supply modulator 30A configured to selectively output, based on an envelope signal of the RF signal S1, at least one of the plurality of discrete voltages to the PA 2A; and the supply modulator 30B configured to selectively output, based on an envelope signal of the RF signal S2, at least one of the plurality of discrete voltages to the PA 2B. The PA 2A is configured to amplify the RF signal S1. The PA 2B is configured to amplify the RF signal S2. The RF signal S1 is a Sub6 signal of a cellular network. The RF signal S2 is a 5 GHz band signal of a WLAN.

Accordingly, at least one voltage selected from among the plurality of discrete voltages based on the envelope signal of the WLAN signal is supplied as the power supply voltage V_{ETB} to the PA 2B. In general, a WLAN signal has a large band width, and thus the change rate of amplitude variation of the envelope signal is high (i.e., the envelope signal changes fast). Thus, for amplification of the WLAN signal, it is difficult to use the analog ET mode, and the APT mode or a fixed voltage mode is often used. Use of the digital ET mode for amplification of such a WLAN signal makes it possible to improve PAE. Furthermore, according to the present exemplary embodiment, the digital ET mode is applied to both the PA 2A that amplifies a cellular network signal and the PA 2B that amplifies a WLAN signal. Thus, the switched-capacitor circuit 20 that generates a plurality of discrete voltages can be shared between the PAs 2A and 2B, which contributes to a decreased size of the power supply circuit 1 (i.e., a decreased area occupied by the power supply circuit 1) compared with a case where the analog ET mode, in which voltage generators are necessary for individual PAs, is applied to the PAs 2A and 2B.

In the present exemplary embodiment, the communication device 7 does not necessarily have to include the PA 2A or the antenna 6A. In this case, the power supply circuit 1 does not necessarily have to include the supply modulator 30A or the filter circuit 40.

### Third Exemplary Embodiment

Next, a third embodiment will be described. The present exemplary embodiment is different from the above-described first and second embodiments mainly in that the PA 2B is configured to amplify a millimeter-wave signal of a cellular network and that the supply modulator 30B is included in a PA module. Hereinafter, the present exemplary embodiment will be described with a focus on differences from the above-described first and second embodiments.

The circuit configurations of the communication device 7 and the power supply circuit 1 and the power supply voltage supply method according to the present exemplary embodiment are similar to those of the above-described first embodiment, and thus the description thereof is omitted.

### [3.1. Disposition of Modules]

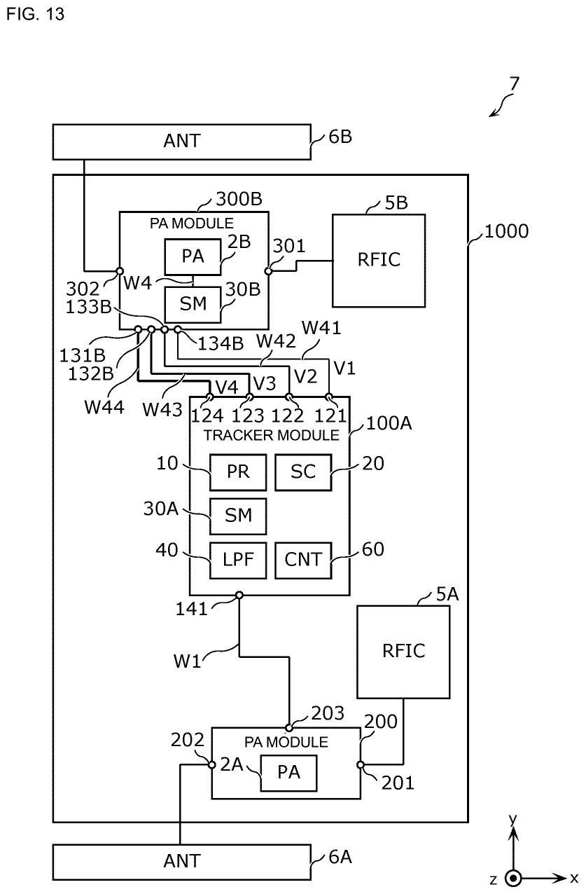

The disposition of the tracker module 100A, the PA module 200, a PA module 300B, and so forth on the mother substrate 1000 of the communication device 7 will be described with reference to FIG. 13. FIG. 13 is a layout diagram of the modules on the mother substrate 1000 according to the present exemplary embodiment.

The PA module 300B includes the PA 2B configured to amplify a millimeter-wave signal of a cellular network, and the supply modulator 30B (SM). In the PA module 300B, the PA 2B and the supply modulator 30B are connected to each other via a wiring line W4. The length of the wiring line W4 may be shorter than the length of the wiring line W1, and the width of the wiring line W4 may be larger than the width of the wiring line W1.

The PA module 300B has the input terminals 131B to 134B. The input terminals 131B to 134B are connected to the tracker module 100A via wiring lines W44 to W41. According to some exemplary aspects, the input terminal 131B is connected to the output terminal 124 of the tracker module 100A via the wiring line W44. The input terminal 132B is connected to the output terminal 123 of the tracker module 100A via the wiring line W43. The input terminal 133B is connected to the output terminal 122 of the tracker module 100A via the wiring line W42. The input terminal 134B is connected to the output terminal 121 of the tracker module 100A via the wiring line W41. Accordingly, the voltages V4 to V1 are applied from the switched-capacitor circuit 20 to the input terminals 131B to 134B, respectively. The length of the wiring line W44 may be shorter than the length of the wiring line W41, and the width of the wiring line W44 may be larger than the width of the wiring line W41.

### [3.2. Configuration of PA Module 300B]

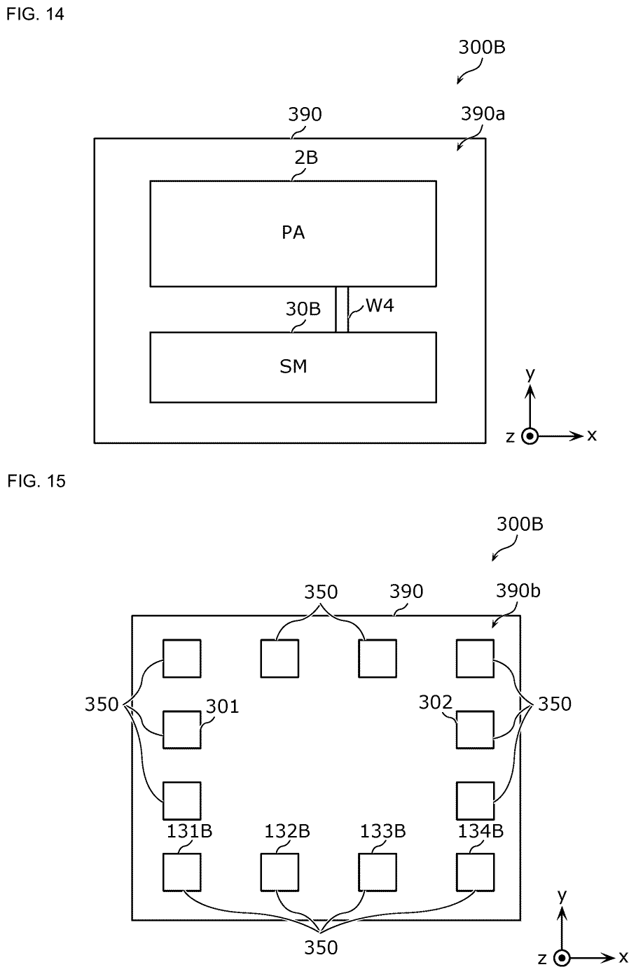

Next, the configuration of the PA module 300B will be described with reference to FIG. 14 and FIG. 15. FIG. 14 is a plan view of the PA module 300B according to the present exemplary embodiment. FIG. 15 is a plan view of the PA module 300B according to the present exemplary embodiment, in which the main surface 390b side of the module laminate 390 is seen through from the positive side of the z-axis.

In FIG. 14 and FIG. 15, the illustration of wiring lines connecting a plurality of circuit components disposed on or in the module laminate 390 is partially omitted. In FIG. 14 and FIG. 15, the illustration of a resin member covering the plurality of circuit components and a shield electrode layer covering the surface of the resin member is omitted.

The PA module 300B includes the module laminate 390 and a plurality of land electrodes 350 in addition to the PA 2B and the supply modulator 30B.

The PA 2B and the supply modulator 30B are disposed on a main surface 390a. The PA 2B and the supply modulator 30B are connected to each other via the wiring line W4. The power supply voltage V_{ETB} is supplied from the supply modulator 30B to the PA 2B via the wiring line W4.

The PA 2B is mounted in, for example, an integrated circuit. In this case, the integrated circuit may be composed of at least one of silicon (Si), gallium arsenide (GaAs), silicon germanium (SiGe), and gallium nitride (GaN), but the material of the integrated circuit is not limited thereto.

In an exemplary aspect, the supply modulator 30B is mounted in an integrated circuit formed by using, for example, CMOS. In this case, the integrated circuit may be manufactured by an SOI process, for example, but it is noted that the integrated circuit is not limited to CMOS in alterative aspects.

The plurality of land electrodes 350 are disposed on the main surface 390b. The plurality of land electrodes 350 function as a plurality of external connection terminals including ground terminals in addition to the input terminals 131B to 134B and 301, and the output terminal 302 illustrated in FIG. 13.

The plurality of land electrodes 350 are electrically connected to input and output terminals and/or ground terminals on the mother substrate 1000 disposed in the z-axis negative direction of the PA module 300B. In addition, the plurality of land electrodes 350 are electrically connected to the PA 2B and the supply modulator 30B disposed on the main surface 390a via the via-conductors or the like formed in the module laminate 390.

The configuration of the PA module 300B according to the present exemplary embodiment is illustrative and is not restrictive. For example, the PA module 300B may include a part or the entirety of the RFIC 5B.

Alternatively, the communication device 7 may include a plurality of PA modules 300B. In this case, the tracker module 100A may supply the plurality of voltages V1 to V4 to the plurality of PA modules 300B. Accordingly, the tracker module 100A is shared among the plurality of PAs 2B, which is effective in reducing the size of the communication device 7.

### [3.3. Advantageous Effects and the Like]

As described above, the power supply circuit 1 according to the present exemplary embodiment includes the switched-capacitor circuit 20 configured to generate, based on an input voltage, a plurality of discrete voltages; the supply modulator 30A configured to selectively output, based on an envelope signal of the RF signal S1, at least one of the plurality of discrete voltages to the PA 2A; and the supply modulator 30B configured to selectively output, based on an envelope signal of the RF signal S2, at least one of the plurality of discrete voltages to the PA 2B. The PA 2A is configured to amplify the RF signal S1. The PA 2B is configured to amplify the RF signal S2. The RF signal S1 is a Sub6 signal of a cellular network. The RF signal S2 is a millimeter-wave signal of a cellular network.

Accordingly, at least one voltage selected from among the plurality of discrete voltages based on the envelope signal of the millimeter-wave signal is supplied as the power supply voltage V_{ETB} to the PA 2B. In general, a larger band width is used in a higher frequency, and thus, in a millimeter-wave signal, the band width is large, and the change rate of amplitude variation of the envelope signal is high (i.e., the envelope signal changes fast). Thus, for amplification of the millimeter-wave signal, it is difficult to use the analog ET mode, and the APT mode or a fixed voltage mode is often used. Use of the digital ET mode for amplification of such a millimeter-wave signal makes it possible to improve PAE. Furthermore, according to the present exemplary embodiment, the digital ET mode is applied to both the PA 2A that amplifies a Sub6 signal and the PA 2B that amplifies a millimeter-wave signal. Thus, the switched-capacitor circuit 20 that generates a plurality of discrete voltages can be shared between the PAs 2A and 2B, which contributes to a decreased size of the power supply circuit 1 (i.e., a decreased area occupied by the power supply circuit 1) compared with a case where the analog ET mode, in which voltage generators are necessary for individual PAs, is applied to the PAs 2A and 2B.

For example, in the power supply circuit 1 according to the present exemplary embodiment, the switched-capacitor circuit 20 and the supply modulator 30A may be mounted on or in the module laminate 90. The module laminate may include the output terminal 141 connected to the PA 2A and the plurality of output terminals 121 to 124 connected to the supply modulator 30B. The output terminal 141 may be disposed along the lower side of the module laminate 90. The plurality of output terminals 121 to 124 may be disposed along the upper side of the module laminate 90.

Accordingly, the output terminal 141 connected to the PA 2A and the output terminals 121 to 124 connected to the supply modulator 30B are disposed along the sides opposed to each other of the module laminate 90. Thus, the flexibility of the disposition of the PAs 2A and 2B and the power supply circuit 1 can be increased, and the lengths of the wiring lines for connecting the PAs 2A and 2B to the power supply circuit 1 can be easily shortened.

For example, in the power supply circuit 1 according to the present exemplary embodiment, the module laminate 90 may be disposed between the PAs 2A and 2B.

Accordingly, the length of the wiring line for connecting the output terminal 141 to the PA 2A can be shortened, and the lengths of the wiring lines for connecting the output terminals 121 to 124 to the supply modulator 30B can be shortened. As a result of the length of the wiring line for connecting the output terminal 141 to the PA 2A being shortened, deterioration of a power supply voltage signal resulting from a parasitic capacitance and/or a parasitic inductance can be reduced. As a result of the lengths of the wiring lines for connecting the output terminals 121 to 124 to the supply modulator 30B being shortened, resistance loss caused by wiring lines can be reduced.

For example, in the power supply circuit 1 according to the present exemplary embodiment, the switched-capacitor circuit 20 and the supply modulators 30A and 30B may be mounted on or in the module laminate 90. The module laminate 90 may include the output terminal 141 connected to the PA 2A and the plurality of output terminals 121 to 124 connected to the supply modulator 30B. The output terminals 141 and 121 to 124 may be disposed along the same side of the module laminate 90.

Accordingly, in a case where the PAs 2A and 2B are disposed in similar directions with respect to the module laminate 90, for example, the lengths of the wiring lines for connecting the power supply circuit 1 to the PAs 2A and 2B can be easily shortened.

For example, in the power supply circuit 1 according to the present exemplary embodiment, the RF signal S1 may be a transmission signal of FDD. The power supply circuit 1 may further include the filter circuit 40 connected to the supply modulator 30A. The supply modulator 30A may be configured to selectively output at least one of the plurality of discrete voltages to the PA 2A via the filter circuit 40.

Accordingly, the power supply voltage V_{ETA} is supplied to the PA 2A via the filter circuit 40, which makes it possible to reduce a decrease in the reception sensitivity of a reception signal of FDD resulting from noise included in the signal of the power supply voltage V_{ETA}.

For example, in the power supply circuit 1 according to the present exemplary embodiment, the filter circuit 40 may be mounted on or in the module laminate 90.

This contributes to a decreased size of the communication device 7.

For example, the power supply circuit 1 according to the present exemplary embodiment may further include the pre-regulator circuit 10 that converts the input voltage by using the power inductor L71.

Accordingly, variations in the input voltage of the switched-capacitor circuit 20 resulting from voltage variations of the DC power source 50 can be reduced, and the stability of the voltage levels of the plurality of discrete voltages generated by the switched-capacitor circuit 20 can be increased.

### Fourth Exemplary Embodiment

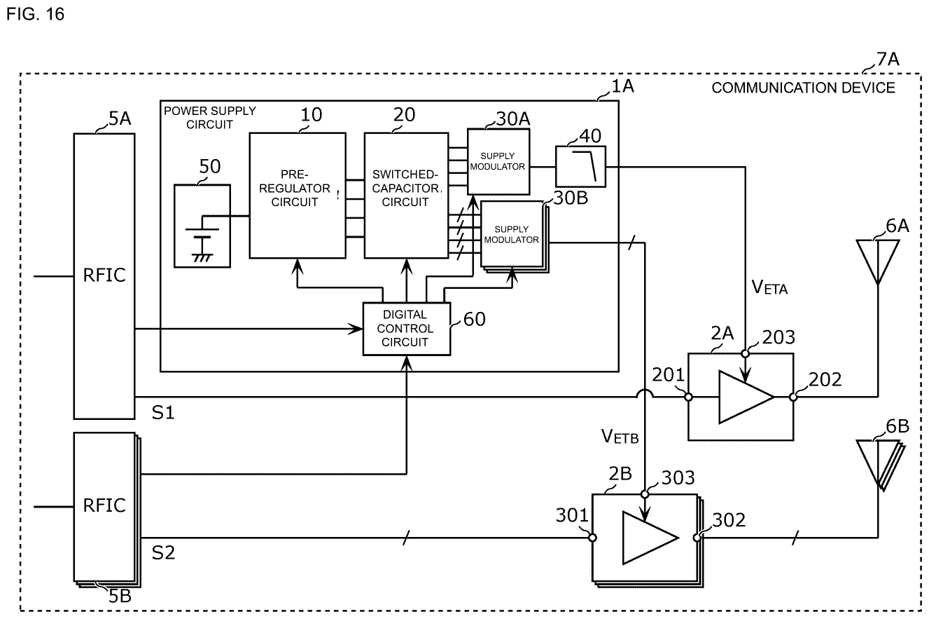

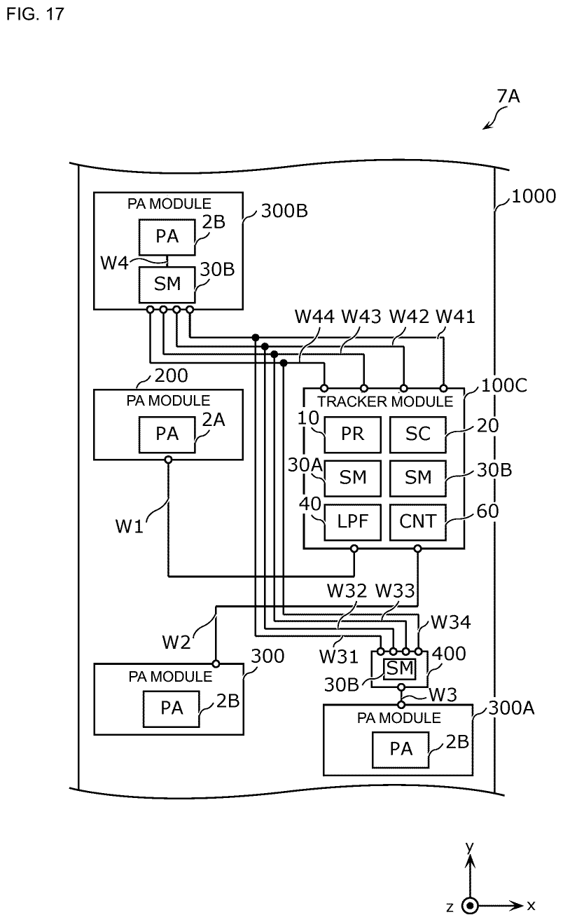

Next, a fourth embodiment will be described. The present exemplary embodiment is different from the above-described first to third embodiments mainly in that the communication device includes the four PA modules 200, 300, 300A, and 300B described in the first to third embodiments. Hereinafter, the present exemplary embodiment will be described with a focus on differences from the above-described first to third embodiments with reference to FIG. 16 and FIG. 17.

FIG. 16 is a circuit configuration diagram of a communication device 7A according to the present exemplary embodiment. The communication device 7A according to the present exemplary embodiment includes a power supply circuit 1A, the PA 2A, three PAs 2B, the RFIC 5A, three RFICs 5B, the antenna 6A, and three antennas 6B. The three PAs 2B are configured to amplify a 2.4 GHz band signal of a WLAN, a 5 GHz band signal of a WLAN, and a millimeter-wave signal of a cellular network, respectively.

The power supply circuit 1A includes the pre-regulator circuit 10, the switched-capacitor circuit 20, the supply modulator 30A, three supply modulators 30B, the filter circuit 40, the DC power source 50, and the digital control circuit 60.

One of the three supply modulators 30B is configured to selectively output, based on a digital control signal corresponding to an envelope of a 2.4 GHz band signal of a WLAN, at least one of a plurality of discrete voltages to one of the PAs 2B. Another one of the supply modulators 30B is configured to selectively output, based on an envelope of a 5 GHz band signal of a WLAN, at least one of the plurality of discrete voltages to another one of the PAs 2B. The other one of the supply modulators 30B is configured to selectively output, based on an envelope of a millimeter-wave signal of a cellular network, at least one of the plurality of discrete voltages to the other one of the PAs 2B.

FIG. 17 is a layout diagram of the modules on the mother substrate 1000 according to the present exemplary embodiment. In FIG. 17, the illustration of the RFICs 5A and 5B and the antennas 6A and 6B is omitted.

The PA module 200 includes the PA 2A configured to amplify a Sub6 signal of a cellular network. The PA module 300 includes the PA 2B configured to amplify a 2.4 GHz band signal of a WLAN. The PA module 300A includes the PA 2B configured to amplify a 5 GHz band signal of a WLAN. The PA module 300B includes the PA 2B configured to amplify a millimeter-wave signal of a cellular network.

A tracker module 100C is configured to supply voltages to the PA modules 200, 300, 300A, and 300B, and includes the pre-regulator circuit 10 (PR), the switched-capacitor circuit 20 (SC), the supply modulators 30A and 30B (SM), the filter circuit 40 (LPF), and the digital control circuit 60 (CNT).

According to some exemplary aspects, the tracker module 100C is connected to the PA modules 200 and 300 via the wiring lines W1 and W2, respectively, and is configured to supply voltages selected by the supply modulators 30A and 30B to the PA modules 200 and 300, respectively. In addition, the tracker module 100C is connected to the integrated circuit 400 via the wiring lines W31 to W34 and is configured to apply the voltages V1 to V4 each having a corresponding one of a plurality of discrete voltage levels and generated by the switched-capacitor circuit 20 to the integrated circuit 400. In addition, the tracker module 100C is connected to the PA module 300B via the wiring lines W41 to W44 and is configured to apply the voltages V1 to V4 each having a corresponding one of a plurality of discrete voltage levels and generated by the switched-capacitor circuit 20 to the PA module 300B.

The length of the wiring line W44 may be shorter than the length of the wiring line W34, and the width of the wiring line W44 may be larger than the width of the wiring line W34. Similarly, the length of the wiring line W43 may be shorter than the length of the wiring line W33, and the width of the wiring line W43 may be larger than the width of the wiring line W33. The length of the wiring line W42 may be shorter than the length of the wiring line W32, and the width of the wiring line W42 may be larger than the width of the wiring line W32. The length of the wiring line W41 may be shorter than the length of the wiring line W31, and the width of the wiring line W41 may be larger than the width of the wiring line W31.

The length of the wiring line W34 to which the highest voltage V4 is applied among the wiring lines W31 to W34 may be shorter than the length of the wiring line W31 to which the lowest voltage V1 is applied among the wiring lines W31 to W34. Furthermore, the width of the wiring line W34 may be larger than the width of the wiring line W31. Similarly, the length of the wiring line W44 to which the highest voltage V4 is applied among the wiring lines W41 to W44 may be shorter than the length of the wiring line W41 to which the lowest voltage V1 is applied among the wiring lines W41 to W44. Furthermore, the width of the wiring line W44 may be larger than the width of the wiring line W41.

### Fifth Exemplary Embodiment

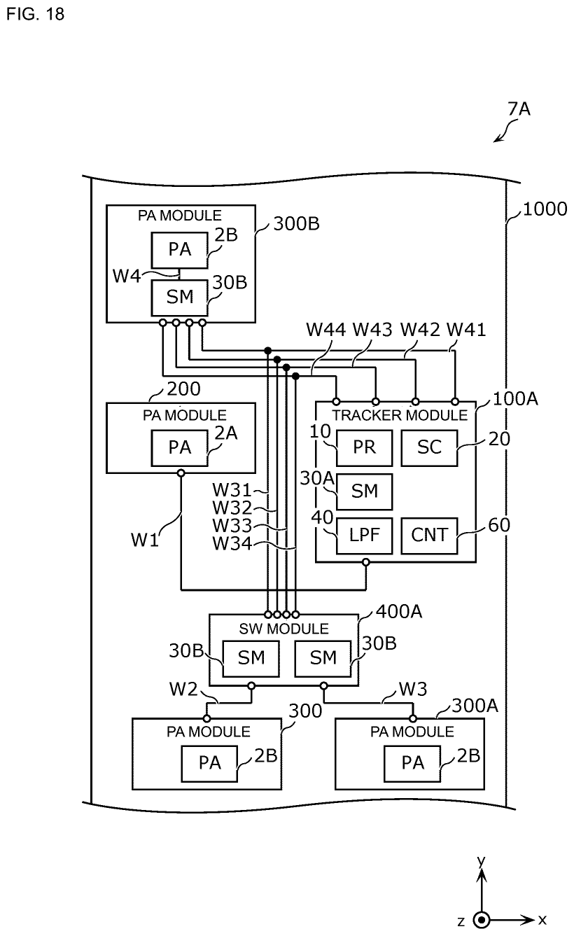

Next, a fifth embodiment will be described. The present exemplary embodiment is different from the above-described fourth embodiment mainly in that two supply modulators 30B are included in one SW module. Hereinafter, the present exemplary embodiment will be described with a focus on differences from the above-described fourth embodiment with reference to FIG. 18.

FIG. 18 is a layout diagram of the modules on the mother substrate 1000 according to the present exemplary embodiment. In FIG. 18, the illustration of the RFICs 5A and 5B and the antennas 6A and 6B is omitted.

In an exemplary aspect, an SW module 400A includes two supply modulators 30B. The SW module 400A includes two integrated circuits formed by using, for example, CMOS, and is disposed on or in a module laminate. The two integrated circuits may be manufactured, for example, by an SOI process. Alternatively, the two integrated circuits may be integrated into one integrated circuit.

In the present exemplary embodiment, the supply modulator 30B included in the PA module 300B may be included in the SW module 400A.

### Additional Exemplary Embodiments

The power supply circuit and the power supply voltage supply method according to the present disclosure have been described above based on the exemplary embodiments. The power supply circuit and the power supply voltage supply method according to the present disclosure are not limited to the above-described exemplary embodiments. Another exemplary embodiment implemented by combining any constituent elements in the above-described exemplary embodiments, modifications obtained by applying various changes conceived by those skilled in the art to the above-described exemplary embodiments without departing from the gist of the present disclosure, and various devices including the above-described power supply circuit are also included in the present disclosure.

For example, in the circuit configurations of the various circuits according to the above-described exemplary embodiments, another circuit element, wiring line, and the like may be inserted between individual circuit elements and paths connecting signal paths disclosed in the drawings. For example, a filter may be inserted between the PA 2A and the antenna 6A and/or between the PA 2B and the antenna 6B.

In the above-described exemplary embodiments, the power supply circuits 1 and 1A supply a power supply voltage to the PA configured to amplify a Sub6 signal of 5G NR. Alternatively, a power supply voltage may be supplied to the PA configured to amplify an LTE signal in addition to the PA configured to amplify a Sub6 signal of 5G NR or instead of the PA configured to amplify a Sub6 signal of 5G NR.

In the above-described exemplary embodiments, a plurality of voltages each having a corresponding one of a plurality of discrete voltage levels are supplied from the switched-capacitor circuit to the supply modulator, but the present disclosure is not limited thereto. For example, a plurality of voltages may each be supplied from one of a plurality of DC-DC converters. In a case where the plurality of discrete voltage levels are equally spaced, a switched-capacitor circuit is used, which is effective in reducing the size of the tracker module.

In the above-described exemplary embodiments, a power supply voltage variable to four discrete voltage levels is supplied, but the number of discrete voltage levels is not limited to four. For example, when the plurality of discrete voltage levels include at least a voltage level corresponding to maximum output power and a voltage level corresponding to output power having the highest occurrence frequency, the PAE can be effectively improved.

In the above-described exemplary embodiments, the power supply circuits 1 and 1A include two or four supply modulators, but the number of supply modulators is not limited to these numbers. The number of supply modulators connected to one switched-capacitor circuit may be any number.

In the above-described exemplary embodiments, a Sub6 signal and a millimeter-wave signal of a cellular network, and a 2.4 GHz band signal and a 5 GHz band signal of a WLAN are used as the RF signals S1 and S2, but the signals are not limited thereto. For example, a 6 GHz band signal and/or a 7 GHz band signal of a WLAN may be used as the RF signal S1 and/or the RF signal S2. Furthermore, for example, a signal in the frequency range 3 (FR3) of a cellular network may be used as the RF signal S1 and/or the RF signal S2. Furthermore, for example, a radar signal may be used as the RF signal S1 and/or the RF signal S2.

In a typical wireless technology, multiple simultaneous wireless transmissions can be used to increase data rates or improve other aspects of connection performance. For example, the approach of Multiple-Input and Multiple-Output (MIMO) utilizes multiple simultaneous wireless signal transmissions in the same frequency. In another example, Carrier Aggregation (CA) utilizes multiple simultaneous wireless signal transmissions in different frequencies in a cellular application. In another example, a Concurrent Dual Band (CDB) operation utilizes multiple transmissions in different frequencies in a WLAN application.

The signals of such multiple simultaneous wireless transmissions may be used as the RF signals S1 and S2, additional RF signals, or any combination thereof. For example, as the RF signals S1 and S2, additional RF signals, or any combination thereof, a plurality of FR1 or FR2 signals for CA or E-UTRAN New Radio-Dual Connectivity (ENDC) of a cellular network may be used. For example, as the RF signals S1 and S2, additional RF signals, or any combination thereof, a plurality of FR1 or FR2 signals for dual Subscriber Identity Module (SIM) or MIMO of a cellular network may be used. For example, as the RF signals S1 and S2, additional RF signals, or any combination thereof, a plurality of signals for MIMO or CDB of a WLAN may be used. For example, as the RF signals S1 and S2, additional RF signals, or any combination thereof, FR1, FR2, and FR3 signals of a cellular network may be used.

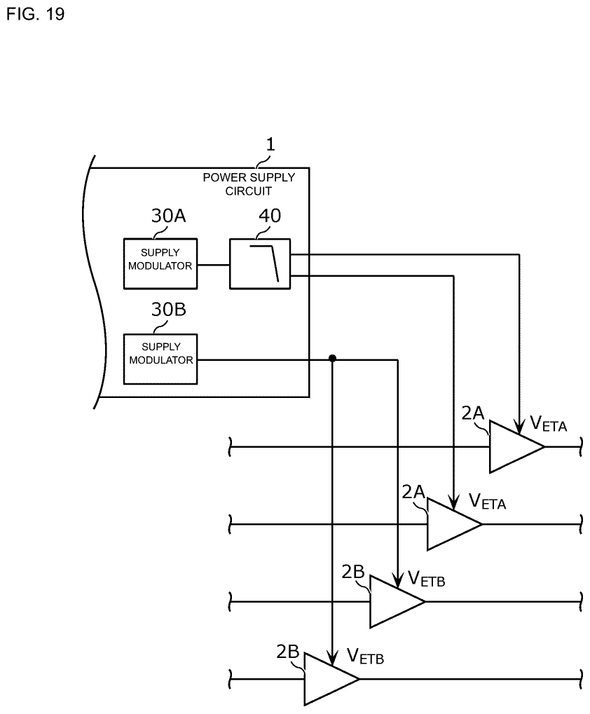

In the above-described exemplary embodiments, each of the supply modulators 30A and 30B is connected to one PA but may be connected to a plurality of PAs. For example, in FIG. 19, the supply modulator 30A is configured to selectively supply the power supply voltage V_{ETA} to two PAs 2A, and the supply modulator 30B is configured to simultaneously supply the power supply voltage V_{ETB} to two PAs 2B that amplify the same modulated RF signal.

In general, it is noted that the present disclosure can be widely used, as a power supply circuit for supplying a power supply voltage to a PA, in communication devices such as mobile phones.

### REFERENCE SIGNS LIST

1, 1A power supply circuit
2A, 2B power amplifier
5A, 5B RFIC
6A, 6B antenna
7, 7A communication device
10 pre-regulator circuit
20 switched-capacitor circuit
30A, 30B supply modulator
40 filter circuit
50 DC power source
60 digital control circuit
61 first controller
62 second controller
80, 400 integrated circuit
80a PR switch portion
80b SC switch portion
80cA, 80cB SM switch portion
80d digital control portion
90, 290, 390 module laminate
90a, 90b, 290a, 290b, 390a, 390b main surface
90b1 central region
90b2 peripheral region
91 resin member
93 shield electrode layer
94 ground plane
100, 100A, 100C tracker module
110, 131A, 131B, 132A, 132B, 133A, 133B, 134A, 134B, 140, 201, 301 input terminal
111, 112, 113, 114, 121, 122, 123, 124, 130A, 130B, 141, 202, 302 output terminal
150, 151, 152, 153, 250, 350 land electrode
200, 300, 300A, 300B PA module
203, 303 power supply terminal
400A SW module
601, 602, 603, 604, 605, 606 control terminal
1000 mother substrate
C10, C11, C12, C13, C14, C15,C16, C20,C30,C40, C51, C52, C61, C62, C63,C64 capacitor
L51, L52, L53 inductor
L71 power inductor
N1, N2, N3, N4 node
R51 resistor
CS1, CS2, CS3A, CS3B control signal
S1, S2 radio frequency signal
S11, S12, S13, S14, S21, S22, S23, S24, S31, S32, S33, S34, S41, S42, S43, S44, S51A, S51B, S52A, S52B, S53A, S53B, S54A, S54B, S61, S62, S63, S71, S72 switch
V1, V2, V3, V4 voltage
V_{ETA}, V_{ETB} power supply voltage
W1, W2, W3, W4, W31, W32, W33, W34, W41, W42, W43, W44 wiring line

What is claimed:

1. A power supply circuit comprising:
a switched-capacitor circuit configured to generate, based on an input voltage, a plurality of discrete voltages;
a first supply modulator configured to select, based on a first envelope signal of a first radio frequency signal, at least a first discrete voltage from the plurality of discrete voltages to output to a first power amplifier;
a second supply modulator configured to select, based on a second envelope signal of a second radio frequency signal, at least a second voltage from the plurality of discrete voltages to output to a second power amplifier, wherein:
the first power amplifier is configured to amplify the first radio frequency signal;
the second power amplifier is configured to amplify the second radio frequency signal;
the first radio frequency signal is a cellular network signal; and
the second radio frequency signal is a wireless local area network signal.

2. The power supply circuit according to claim 1, wherein:
the switched-capacitor circuit, the first supply modulator, and the second supply modulator are mounted on or in a module laminate;
the module laminate includes:
a first output terminal connected to the first power amplifier; and
a second output terminal connected to the second power amplifier; and
the first output terminal and the second output terminal are respectively disposed along opposite sides of the module laminate.

3. The power supply circuit according to claim 2, wherein the module laminate is disposed between the first power amplifier and the second power amplifier.

4. The power supply circuit according to claim 1, wherein:
the switched-capacitor circuit, the first supply modulator, and the second supply modulator are mounted on or in a module laminate;
the module laminate includes:
a first output terminal connected to the first power amplifier; and
a second output terminal connected to the second power amplifier; and
the first output terminal and the second output terminal are disposed along a same side of the module laminate.

5. The power supply circuit according to claim 2, wherein:
the first radio frequency signal is a transmission signal of frequency division duplex;
the power supply circuit further comprises a filter circuit connected to the first supply modulator; and
the first supply modulator is configured to select at least the first discrete voltage of the plurality of discrete voltages to output to the first power amplifier via the filter circuit.

6. The power supply circuit according to claim 5, wherein the filter circuit is mounted on or in the module laminate.

7. The power supply circuit according to claim 1, further comprising a pre-regulator circuit configured to convert the input voltage for use in the switched-capacitor circuit by using a power inductor.

8. The power supply circuit according to claim 1, wherein the switched-capacitor circuit, and the first supply modulator, are mounted on or in a first module laminate, and the second supply modulator is mounted on or in a second module laminate.

9. The power supply circuit according to claim 8, wherein the second supply modulator and the second power amplifier are mounted on or in the second module laminate.

10. A power supply circuit comprising:
a switched-capacitor circuit configured to generate, based on an input voltage, a plurality of discrete voltages;
a first supply modulator configured to select, based on a first envelope signal of a first radio frequency signal, at least a first discrete voltage from the plurality of discrete voltages to output to a first power amplifier;
a second supply modulator configured to select, based on a second envelope signal of a second radio frequency signal, at least a second discrete voltage from the plurality of discrete voltages to output to a second power amplifier, wherein:
the first power amplifier is configured to amplify the first radio frequency signal;
the second power amplifier is configured to amplify the second radio frequency signal;
the first radio frequency signal is a Sub6 signal of a cellular network; and
the second radio frequency signal is a millimeter-wave signal of a cellular network.

11. The power supply circuit according to claim 10, wherein:
the switched-capacitor circuit and the first supply modulator are mounted on or in a module laminate;
the module laminate includes:
a first output terminal connected to the first power amplifier; and
a plurality of second output terminals connected to the second supply modulator;
the first output terminal is disposed along a first side of the module laminate; and
the plurality of second output terminals are disposed along a second side of the module laminate that is opposed to the first side of the module laminate.

12. The power supply circuit according to claim 11, wherein the module laminate is disposed between the first power amplifier and the second power amplifier.

13. The power supply circuit according to claim 10, wherein:
the switched-capacitor circuit and the first supply modulator are mounted on or in a module laminate,
the module laminate includes:
a first output terminal connected to the first power amplifier; and
a plurality of second output terminals connected to the second supply modulator, and
the first output terminal and the plurality of second output terminals are disposed along a same side of the module laminate.

14. The power supply circuit according to claim 11, wherein:
the first radio frequency signal is a transmission signal of frequency division duplex;
the power supply circuit further comprises a filter circuit connected to the first supply modulator; and
the first supply modulator is configured to select at least the first discrete voltage from the plurality of discrete voltages to output to the first power amplifier via the filter circuit.

15. The power supply circuit according to claim 14, wherein the filter circuit is mounted on or in the module laminate.

16. The power supply circuit according to claim 10, further comprising a pre-regulator circuit configured to convert the input voltage for use in the switched-capacitor circuit by using a power inductor.

17. The power supply circuit according to claim 10, wherein the switched-capacitor circuit, and the first supply modulator, are mounted on or in a first module laminate, and the second supply modulator is mounted on or in a second module laminate.

18. The power supply circuit according to claim 17, wherein the second supply modulator and the second power amplifier are mounted on or in the second module laminate.

19. A method for power supply comprising:
generating, based on an input voltage, a plurality of discrete voltages;
selecting, based on a first envelope signal of a first radio frequency signal, at least a first discrete voltage from the plurality of discrete voltages as a first power supply voltage;
selecting, based on a second envelope signal of a second radio frequency signal, at least a second discrete voltage from the plurality of discrete voltages as a second power supply voltage;
supplying the first power supply voltage to a first power amplifier configured to amplify the first radio frequency signal;
supplying the second power supply voltage to a second power amplifier configured to amplify the second radio frequency signal,
wherein the first radio frequency signal is a cellular network signal, and the second radio frequency signal is a wireless local area network signal.

20. The method according to claim 19, further comprising:
generating, based on the first envelope signal of the first radio frequency signal, at least a first digitally controlled level signal;
generating, based on the second envelope signal of the second radio frequency signal, at least a second digitally controlled level signal;
selecting the first power supply voltage based on at least the first digitally controlled level signal; and
selecting the second power supply voltage based on at least the second digitally controlled level signal.
